(19) United States
(12) Patent Application Publication
(10) Pub. No.: US 2025/0331225 A1
(43) Pub. Date: Oct. 23, 2025

(54) SiC SEMICONDUCTOR DEVICE

(71) Applicant: ROHM CO., LTD., Kyoto-shi (JP)

(72) Inventors: Seigo MORI, Kyoto-shi (JP); Yuki NAKANO, Kyoto-shi (JP)

(73) Assignee: ROHM CO., LTD., Kyoto-shi (JP)

(21) Appl. No.: 19/252,551

(22) Filed: Jun. 27, 2025

Related U.S. Application Data
(63) Continuation of application No. PCT/JP2023/046699, filed on Dec. 26, 2023.

(30) Foreign Application Priority Data
Dec. 28, 2022 (JP) 2022-212614

(51) Int. Cl. H10D 30/66; H10D 62/832; H10D 64/23; H10D 64/27

(52) U.S. Cl. CPC H10D 30/66; H10D 62/8325; H10D 64/252; H10D 64/258; H10D 64/512; H10D 64/514

(57) ABSTRACT

An SiC semiconductor device includes an SiC chip having a main surface, a channel region formed in a surface layer portion of the main surface, a drift region adjacent to the channel region in the surface layer portion of the main surface, a gate insulating film that is formed on the main surface and has a channel covering portion which covers the channel region and a drift covering portion which covers the drift region, a planar gate electrode that is arranged on the channel covering portion and opposes the channel region across the channel covering portion in a vertical direction, and a planar source electrode that is arranged on the drift covering portion at an interval from the planar gate electrode such as to oppose the planar gate electrode in a horizontal direction and opposes the drift region across the drift covering portion in the vertical direction.

### CROSS-REFERENCE TO RELATED APPLICATIONS

The present application is a bypass continuation of International Patent Application No. PCT/JP2023/046699 filed on Dec. 26, 2023, which claims priority to Japanese Patent Application No. 2022-212614 filed on Dec. 28, 2022 and the entire contents of those applications are hereby incorporated herein by reference.

### BACKGROUND

### 1. Field of the Disclosure

The present disclosure relates to an SiC semiconductor device.

### 2. Description of the Related Art

US2003/0235942A1 discloses a semiconductor device having a lateral MOSFET structure including a gate electrode divided into two. In FIG. 6 of US2003/0235942A1, polysilicon of a p-type is arranged in a region between the gate electrode divided into two. The p-type polysilicon is arranged on a surface of a semiconductor layer as a diffusion source of p-type impurities and forms a p-type electric field relaxation region on the surface of the semiconductor layer. In FIG. 7 of US2003/0235942A1, a metal layer is arranged in a region between the two divided gate electrodes.

The metal layer is arranged on the surface of the semiconductor layer and forms a Schottky junction with the surface of the semiconductor layer.

### BRIEF DESCRIPTION OF DRAWINGS

FIG. 1 is a plan view showing a semiconductor device according to a first embodiment.

FIG. 2 is a cross-sectional view taken along line II-II shown in FIG. 1.

FIG. 3 is a plan view showing a layout example of a chip shown in FIG. 1.

FIG. 4 is an enlarged plan view showing a layout example of an active region together with a first planar structure according to a first configuration example.

FIG. 5 is a cross-sectional view taken along line V-V shown in FIG. 4.

FIG. 6 is an enlarged cross-sectional view showing the first planar structure according to the first configuration example.

FIG. 7A is an enlarged cross-sectional view showing a first planar structure according to a second configuration example.

FIG. 7B is an enlarged cross-sectional view showing a first planar structure according to a third configuration example.

FIG. 7C is an enlarged cross-sectional view showing a first planar structure according to a fourth configuration example.

FIG. 7D is an enlarged cross-sectional view showing a first planar structure according to a fifth configuration example.

FIG. 7E is an enlarged cross-sectional view showing a first planar structure according to a sixth configuration example.

FIG. 7F is an enlarged cross-sectional view showing a first planar structure according to a seventh configuration example.

FIG. 7G is an enlarged cross-sectional view showing a first planar structure according to an eighth configuration example.

FIG. 7H is an enlarged plan view showing a first planar structure according to a ninth configuration example.

FIG. 7I is an enlarged plan view showing a first planar structure according to a tenth configuration example.

FIG. 7J is an enlarged cross-sectional view showing a first planar structure according to an eleventh configuration example.

FIG. 8 is a plan view showing a semiconductor device according to a second embodiment.

FIG. 9 is a cross-sectional view taken along line IX-IX shown in FIG. 8.

FIG. 10 is a plan view showing a layout example of a chip shown in FIG. 8.

FIG. 11 is an enlarged plan view showing a layout example of an active region together with a second planar structure according to a first configuration example.

FIG. 12 is a cross-sectional view taken along line XII-XII shown in FIG. 11.

FIG. 13 is an enlarged cross-sectional view showing the second planar structure.

FIG. 14A is an enlarged cross-sectional view showing a second planar structure according to a second configuration example.

FIG. 14B is an enlarged cross-sectional view showing a second planar structure according to a third configuration example.

FIG. 14C is an enlarged cross-sectional view showing a second planar structure according to a fourth configuration example.

FIG. 14D is an enlarged cross-sectional view showing a second planar structure according to a fifth configuration example.

FIG. 14E is an enlarged cross-sectional view showing a second planar structure according to a sixth configuration example.

FIG. 15 is an enlarged cross-sectional view showing a main part of a semiconductor device according to a third embodiment.

FIG. 16 is an enlarged plan view showing a layout example of an active region of a semiconductor device according to a fourth embodiment.

FIG. 17 is a cross-sectional view taken along line XVII-XVII shown in FIG. 16.

FIG. 18 is an enlarged plan view showing a layout example of an active region of a semiconductor device according to a fifth embodiment.

FIG. 19 is a cross-sectional view taken along line XIX-XIX shown in FIG. 18.

FIG. 20 is an enlarged plan view showing a layout example of an active region of a semiconductor device according to a sixth embodiment.

FIG. 21 is a cross-sectional view taken along line XXI-XXI shown in FIG. 20.

FIG. 22 is a cross-sectional view showing a modification example of a planar insulating film.

### DETAILED DESCRIPTION OF THE PREFERRED EMBODIMENTS

Hereinafter, specific embodiments shall be described in detail with reference to the attached drawings. All of the attached drawings are schematic diagrams, are not strictly illustrated, and are not always matched in relative positional relationships, scales, ratios, angles, etc. Identical reference signs are given to corresponding structures among the attached drawings, and duplicate descriptions thereof shall be omitted or simplified. For the structures whose descriptions have been omitted or simplified, the description given before the omission or simplification shall apply.

When the wording “substantially” is used in this description, the wording includes a numerical value (shape) equal to a numerical value (shape) of the comparison target and also includes numerical errors (shape errors) in a range of ±10% on a basis of the numerical value (shape) of the comparison target. Although the wordings “first,” “second,” “third,” etc., are used in the following description, these are symbols attached to names of the structures in order to clarify the order of description and are not attached with an intention of restricting the names of the structures.

In the following description, a “p-type” or an “n-type” is used to indicate a conductivity type of a semiconductor (impurity), and the “p-type” may be referred to as a “first conductivity type,” and the “n-type” may be referred to as a “second conductivity type.” As a matter of course, the “n-type” may be referred to as a “first conductivity type,” and the “p-type” may be referred to as a “second conductivity type.” The “p-type” is a conductivity type caused by a trivalent element, and the “n-type” is a conductivity type caused by a pentavalent element. Unless otherwise specified, the trivalent element is at least one type among boron, aluminum, gallium, and indium. Unless otherwise specified, the pentavalent element is at least one type among nitrogen, phosphorus, arsenic, antimony, and bismuth.

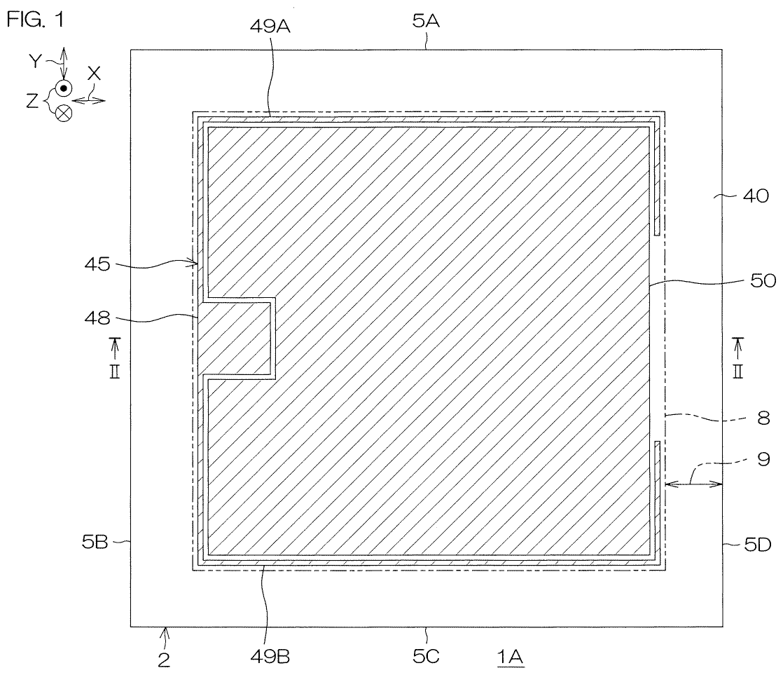

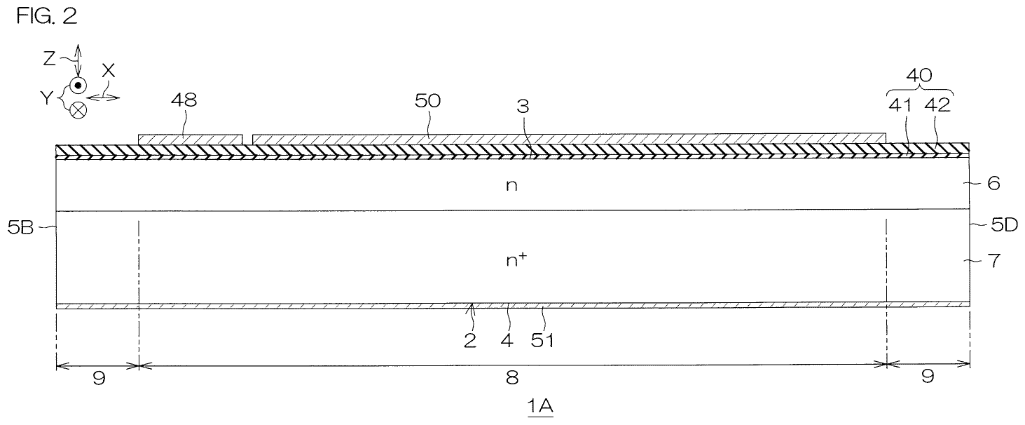

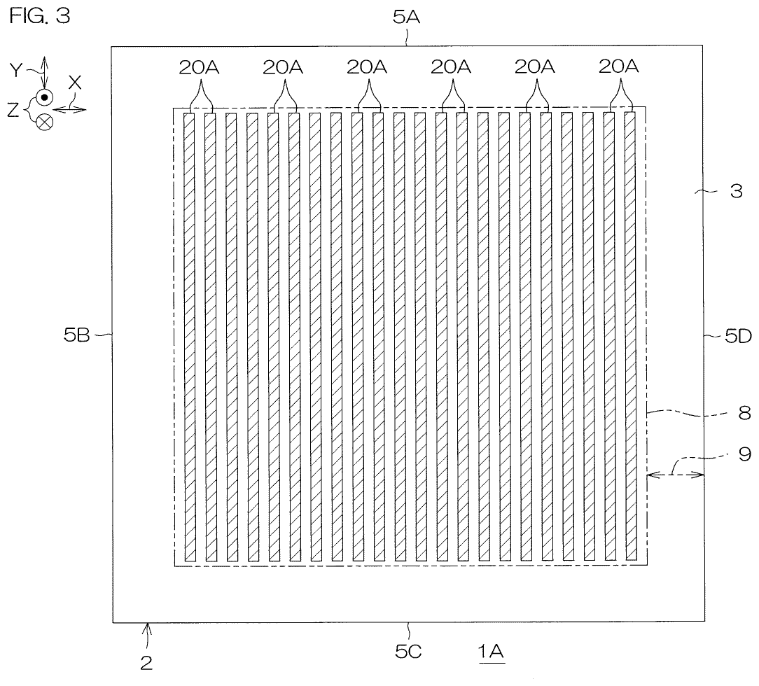

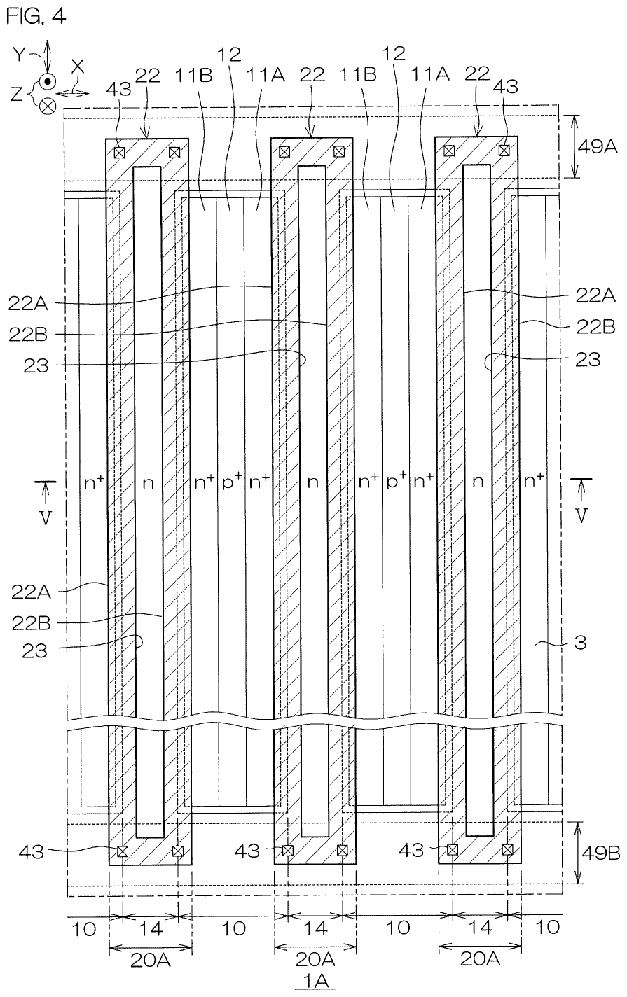

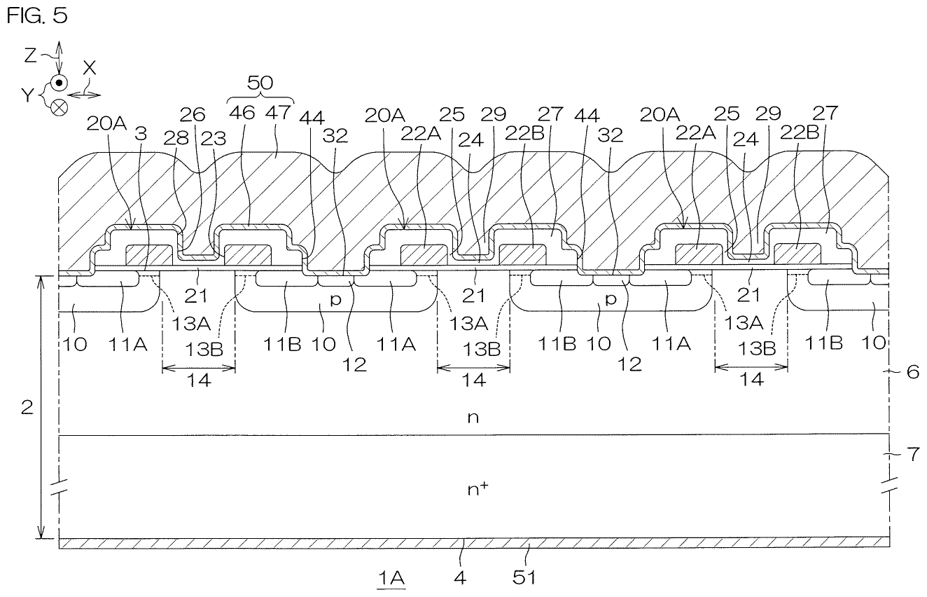

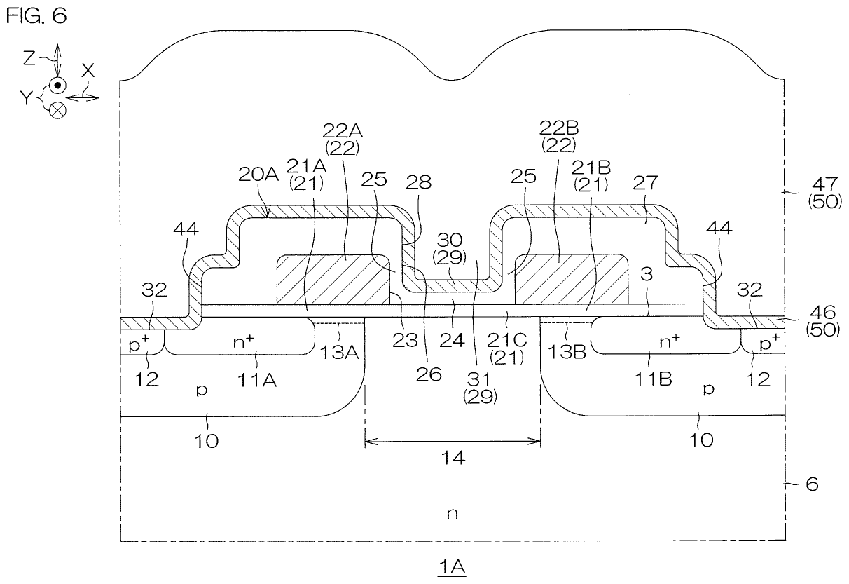

FIG. 1 is a plan view showing an SiC semiconductor device 1A according to a first embodiment. FIG. 2 is a cross-sectional view taken along line II-II shown in FIG. 1. FIG. 3 is a plan view showing a layout example of a chip 2 shown in FIG. 1. FIG. 4 is an enlarged plan view showing a layout example of an active region 8 together with a first planar structure 20A according to a first configuration example. FIG. 5 is a cross-sectional view taken along line V-V shown in FIG. 4. FIG. 6 is an enlarged cross-sectional view showing the first planar structure 20A according to the first configuration example.

With reference to FIGS. 1 to 6, the SiC semiconductor device 1A includes a chip 2 including an SiC monocrystal. The chip 2 may be referred to as a “SiC chip” or as a “semiconductor chip.” In this embodiment, the chip 2 is constituted of an SiC monocrystal that is a hexagonal crystal and is formed in a rectangular parallelepiped shape. The SiC monocrystal that is a hexagonal crystal has a plurality of types of polytypes including a 2H (Hexagonal)-SiC monocrystal, a 4H-SiC monocrystal, a 6H-SiC monocrystal, etc. In this embodiment, an example in which the chip 2 is constituted of the 4H-SiC monocrystal is shown, but the chip 2 may be constituted of another polytype.

The chip 2 has a first main surface 3 on one side, a second main surface 4 on another side, and first to fourth side surfaces 5A to 5D connecting the first main surface 3 and the second main surface 4. The first main surface 3 and the second main surface 4 are each formed in a quadrangular shape in a plan view as viewed in a vertical direction Z (hereinafter simply referred to as a “plan view”). The vertical direction Z is also a thickness direction of the chip 2 or a normal direction of the first main surface 3 (the second main surface 4). The first main surface 3 and the second main surface 4 may be each formed in a square shape or a rectangular shape in a plan view.

Preferably, the first main surface 3 and the second main surface 4 are each formed of a c-plane of the SiC monocrystal. In this case, the first main surface 3 is preferably formed of a silicon plane ((0001) plane) of the SiC monocrystal, and the second main surface 4 is preferably formed of a carbon plane ((000-1) plane) of the SiC monocrystal.

In a circumferential direction (a counterclockwise in FIG. 1) of the chip 2 starting from the first side surface 5A, the second side surface 5B is connected to the first side surface 5A, the third side surface 5C is connected to the second side surface 5B, and the fourth side surface 5D is connected to the first side surface 5A and the third side surface 5C. The first side surface 5A and the third side surface 5C extend in a first direction X that is oriented along the first main surface 3 and oppose each other in a second direction Y that intersects with (specifically, is orthogonal to) the first direction X. The second side surface 5B and the fourth side surface 5D extend in the second direction Y and oppose each other in the first direction X.

In this embodiment, the first direction X is an m-axis direction ([1-100] direction) of the SiC monocrystal, and the second direction Y is an a-axis direction ([11-20] direction) of the SiC monocrystal. As a matter of course, the first direction X may be the a-axis direction of the SiC monocrystal, and the second direction Y may be the m-axis direction of the SiC monocrystal.

An XY plane including the first direction X and the second direction Y forms a horizontal plane orthogonal to the vertical direction Z. Hereinafter, an axis extending in the vertical direction Z may be expressed as a “vertical axis.” Hereinafter, the first direction X and the second direction Y may also be expressed as a “horizontal direction.” The horizontal direction is also a direction extending along the first main surface 3.

The chip 2 (the first main surface 3 and the second main surface 4) may have an off angle inclined in a predetermined off direction at a predetermined angle with respect to the c-plane of the SiC monocrystal. That is, the c-axis ((0001) axis) of the SiC monocrystal is inclined by the off angle from the vertical axis in the off direction. Also, the c-plane of the SiC monocrystal is inclined by the off angle with respect to the horizontal plane.

The off direction is preferably the a-axis direction (that is, the second direction Y) of the SiC monocrystal. The off angle may exceed 0° and be not more than 10°. The off angle may have a value belonging to any one range of exceeding 0° and not more than 1°, not less than 1° and not more than 2.5°, not less than 2.5° and not more than 5°, not less than 5° and not more than 7.5°, and not less than 7.5° and not more than 10°.

The off angle is preferably not more than 5°. The off angle is particularly preferably not less than 2° and not more than 4.5°. The off angle is typically set in a range of 4°+0.1°. As a matter of course, this specification does not exclude a form in which the off angle is 0° (that is, a form in which the first main surface 3 is a just surface with respect to the c-plane).

The SiC semiconductor device 1A includes a drift region 6 of an n-type that is formed in a region (a surface layer portion) on the first main surface 3 side in the chip 2. The drift region 6 may be referred to as a “first semiconductor region,” a “drain drift region,” a “drain region,” etc. A drain potential as a high potential (a first potential) is applied to the drift region 6.

The drift region 6 is formed in a layer shape that extends along the first main surface 3 and is exposed from the first main surface 3 and the first to fourth side surfaces 5A to 5D. In this embodiment, the drift region 6 is constituted of an epitaxial layer (specifically, an SiC epitaxial layer).

The SiC semiconductor device 1A includes a drain region 7 of the n-type that is formed in a region (a surface layer portion) on the second main surface 4 side in the chip 2. A drain potential is applied to the drain region 7. The drain region 7 may be referred to as a “second semiconductor region,” etc. The drain region 7 has an n-type impurity concentration higher than that of the drift region 6 and is electrically connected to the drift region 6 in the chip 2.

The drain region 7 is formed in a layer shape that extends along the second main surface 4 and is exposed from the second main surface 4 and the first to fourth side surfaces 5A to 5D. In this embodiment, the drain region 7 is constituted of a semiconductor substrate (specifically, an SiC substrate). That is, the chip 2 has a laminated structure including the semiconductor substrate and the epitaxial layer. The drain region 7 has a thickness greater than a thickness of the drift region 6.

The SiC semiconductor device 1A includes the active region 8 set in the chip 2. The active region 8 is set in an inner portion of the chip 2 at an interval from a peripheral edge (the first to fourth side surfaces 5A to 5D) of the chip 2 in a plan view. The active regions 8 is set in a polygonal shape (in this embodiment, a quadrangular shape) having four sides parallel to the peripheral edge of the chip 2 in a plan view. A planar area of the active region 8 is preferably not less than 50% and not more than 90% of a planar area of the first main surface 3.

The SiC semiconductor device 1A includes an outer peripheral region 9 set outside the active region 8 in the chip 2. The outer peripheral region 9 is provided in a region between the peripheral edges of the chip 2 and the active region 8 in a plan view. The outer peripheral region 9 extends in a band shape along the active region 8 and is set in a polygonal annular shape (in this embodiment, a quadrangular annular shape) surrounding the active region 8 in a plan view.

The SiC semiconductor device 1A includes a plurality of body regions 10 of the p-type that are formed in a surface layer portion of the first main surface 3 in the active region 8. A source potential as a low potential (a second potential) is applied to the plurality of body regions 10. The plurality of body regions 10 are arranged at intervals in the first direction X and are each formed in a band shape extending in the second direction Y. That is, the plurality of body regions 10 are arranged at intervals in the m-axis direction of the SiC monocrystal and extend in the a-axis direction of the SiC monocrystal. Also, the plurality of body regions 10 are formed in a stripe shape extending in the second direction Y (the a-axis direction).

The SiC semiconductor device 1A includes a plurality of source regions 11A and 11B of the n-type that are each formed in surface layer portions of the plurality of body regions 10 in the active region 8. A source potential is applied to the plurality of body regions 10. The plurality of source region 11A and 11B have an n-type impurity concentration higher than a n-type impurity concentration of the drift region 6.

In this embodiment, the plurality of source regions 11A and 11B are formed in the surface layer portion of each body region 10. Specifically, the plurality of source regions 11A and 11B include a first source region 11A and a second source region 11B formed in the surface layer portion of each body region 10. In this embodiment, in the first direction X, one first source region 11A is formed on one end side of the body region 10, and one second source region 11B is formed on the other end side of the body region 10.

The first source region 11A is formed at an interval from one end toward the other end side of the body region 10 and extends in a band shape in an extension direction of the body region 10.

In a case in which the plurality of first source regions 11A are formed in the body region 10, the plurality of first source regions 11A may be formed at intervals in the extension direction of the body region 10. The first source region 11A is formed at an interval from a bottom portion of the body region 10 toward the first main surface 3 side and opposes the drift region 6 across a part of the body region 10.

The second source region 11B is formed at an interval from the first source region 11A toward the other end side of the body region 10. The second source region 11B is formed at an interval from the other end toward the one end side of the body region 10 and extends in a band shape in the extension direction of the body region 10. In a case in which the plurality of second source regions 11B are formed in the body region 10, the plurality of second source regions 11B may be formed at intervals in the extension direction of the body region 10. The second source region 11B is formed at an interval from the bottom portion of the body region 10 toward the first main surface 3 side and opposes the drift region 6 across a part of the body region 10.

The SiC semiconductor device 1A includes a plurality of contact regions 12 of the p-type that are each formed in the surface layer portions of the plurality of body regions 10 in the active region 8. The contact region 12 may be referred to as a “back gate region.” A source potential is applied to the plurality of contact regions 12. The contact region 12 has a p-type impurity concentration higher than a p-type impurity concentration of the body region 10.

In this embodiment, one contact region 12 is interposed in a region between the plurality of source regions 11A and 11B adjacent to each other in the surface layer portion of the corresponding body region 10. That is, each contact region 12 is interposed in a region between the first source region 11A and the second source region 11B in the surface layer portion of each body region 10.

The contact region 12 extends in a band shape in the extension direction of the body region 10. In a case in which the plurality of contact regions 12 are formed in the body region 10, the plurality of contact regions 12 may be formed at intervals in the extension direction of the body region 10. In this case, each contact region 12 may be formed in a band shape extending in the second direction Y.

In the second direction Y, the contact region 12 may be formed at an interval inward from a peripheral edge of the body region 10, or may have a portion positioned in the drift region 6 across the peripheral edge of the body region 10. The contact region 12 is formed at an interval from the bottom portion of the body region 10 toward the first main surface 3 side and opposes the drift region 6 across a part of the body region 10.

The SiC semiconductor device 1A includes a plurality of channel regions 13A and 13B of the p-type that are formed in the surface layer portion of the first main surface 3. The plurality of channel regions 13A and 13B are each defined in regions between the peripheral edges of the plurality of body regions 10 and peripheral edges of the plurality of source regions 11A and 11B in the surface layer portions of the plurality of body regions 10.

In this embodiment, the plurality of channel regions 13A and 13B are arranged at intervals in the first direction X and are each formed in a band shape extending in the second direction Y. That is, the plurality of channel regions 13A and 13B are arranged at intervals in the m-axis direction of the SiC monocrystal and extend in the a-axis direction of the SiC monocrystal. Also, the plurality of channel regions 13A and 13B are formed in a stripe shape extending in the second direction Y (the a-axis direction).

Specifically, the plurality of channel regions 13A and 13B include a plurality of first channel regions 13A and a plurality of second channel regions 13B. The plurality of first channel regions 13A are each defined in regions between one end of each of the plurality of body regions 10 and the plurality of first source regions 11A and form a current path extending in the horizontal direction. The plurality of second channel regions 13B are each defined in regions between the other ends of the plurality of body regions 10 and the plurality of second source regions 11B and form a current path extending in the horizontal direction.

The SiC semiconductor device 1A includes a plurality of surface layer drift regions 14 of the n-type that are formed in the surface layer portion of the first main surface 3. In this embodiment, the plurality of surface layer drift regions 14 are each constituted of a part of the drift region 6. As a matter of course, the plurality of surface layer drift regions 14 may have an n-type impurity concentration higher than that of the drift region 6.

The plurality of surface layer drift regions 14 are each defined in regions between the plurality of adjacent body regions 10 and are interposed between the first channel regions 13A and the second channel regions 13B. In the surface layer portion of the first main surface 3, the plurality of surface layer drift regions 14 form a current path reaching the first source region 11A through the first channel region 13A and form a current path reaching the second source region 11B through the second channel region 13B.

In this embodiment, the plurality of surface layer drift regions 14 are arranged at intervals in the first direction X and are each formed in a band shape extending in the second direction Y. That is, the plurality of surface layer drift regions 14 are arranged at intervals in the m-axis direction of the SiC monocrystal and extend in the a-axis direction of the SiC monocrystal. Also, the plurality of surface layer drift regions 14 are formed in a stripe shape extending in the second direction Y (the a-axis direction).

The SiC semiconductor device 1A includes a plurality of the first planar structures 20A that are arranged on the first main surface 3 in the active region 8. Each of the plurality of first planar structures 20A includes a gate insulating film 21 that covers the first main surface 3. The gate insulating film 21 may include at least one of a silicon oxide film, a silicon nitride film, and a silicon oxynitride film. In this embodiment, the gate insulating film 21 has a single layer structure constituted of a silicon oxide film. The gate insulating film 21 particularly preferably includes a silicon oxide film constituted of an oxide of the chip 2.

In this embodiment, a plurality of gate insulating films 21 are arranged at intervals in the first direction X and are each formed in a band shape extending in the second direction Y. That is, the plurality of gate insulating films 21 are arranged at intervals in the m-axis direction of the SiC monocrystal and extend in the a-axis direction of the SiC monocrystal. Also, an extension direction of the plurality of gate insulating films 21 is matched with an off direction of the SiC monocrystal.

Each gate insulating film 21 is arranged such as to extend across two adjacent body regions 10 and covers the plurality of channel regions 13A and 13B and the surface layer drift region 14. Specifically, each gate insulating film 21 is arranged such as to extend across the first source region 11A on one body region 10 side and the second source region 11B on the other body region 10 side and covers the first source region 11A, the second source region 11B, the first channel region 13A, the second channel region 13B, and the surface layer drift region 14.

Each gate insulating film 21 includes a first channel covering portion 21A (a first portion) that covers the first channel region 13A in a film shape, a second channel covering portion 21B (a second portion) that covers the second channel region 13B in a film shape, and a drift covering portion 21C (a third portion) that covers the surface layer drift region 14 in a film shape.

The first channel covering portion 21A partially covers the first source region 11A at an interval from the contact region 12 and exposes a part of the first source region 11A and the contact region 12 from the first main surface 3. The second channel covering portion 21B partially covers the second source region 11B at an interval from the contact region 12 and exposes a part of the second source region 11B and the contact region 12 from the first main surface 3. The drift covering portion 21C is continuous to the first channel covering portion 21A and the second channel covering portion 21B.

Each of the plurality of first planar structures 20A includes a planar gate electrode 22 arranged on the gate insulating film 21. A gate potential as a control potential is applied to the planar gate electrode 22. The planar gate electrode 22 may include either or both of p-type conductive polysilicon and n-type conductive polysilicon. The conductivity type of the planar gate electrode 22 is adjusted in accordance with the gate threshold voltage to be achieved.

The planar gate electrode 22 is formed in a band shape extending in the second direction Y on the gate insulating film 21. That is, the planar gate electrode 22 extends in the a-axis direction of the SiC monocrystal. Also, an extension direction of the planar gate electrode 22 is matched with the off direction of the SiC monocrystal.

The planar gate electrode 22 opposes the plurality of channel regions 13A and 13B across the gate insulating film 21 in the vertical direction Z and controls inversion and non-inversion of the plurality of channel regions 13A and 13B in response to a gate potential from the outside. Specifically, the planar gate electrode 22 covers the first channel covering portion 21A and the second channel covering portion 21B, opposes the first channel region 13A across the first channel covering portion 21A, and opposes the second channel region 13B across the second channel covering portion 21B.

The planar gate electrode 22 is led out from above the first channel covering portion 21A onto the drift covering portion 21C and has a portion opposing the surface layer drift region 14 across the drift covering portion 21C. The planar gate electrode 22 is led out from above the second channel covering portion 21B onto the drift covering portion 21C and has a portion opposing the surface layer drift region 14 across the drift covering portion 21C.

The planar gate electrode 22 is preferably formed at an interval from a width direction intermediate portion of the drift covering portion 21C toward the first channel covering portion 21A side and formed at an interval from the width direction intermediate portion of the drift covering portion 21C toward the second channel covering portion 21B. That is, a hiding area of the planar gate electrode 22 with respect to the drift covering portion 21C is preferably less than an exposed area of the drift covering portion 21C.

An opposing area of the planar gate electrode 22 with respect to the surface layer drift region 14 may be less than an opposing area of the planar gate electrode 22 with respect to the first channel region 13A. The opposing area of the planar gate electrode 22 with respect to the surface layer drift region 14 may be less than the opposing area of the planar gate electrode 22 with respect to the second channel region 13B.

The planar gate electrode 22 has a through hole 23 that exposes the drift covering portion 21C. The through hole 23 is formed at an interval inward from the first channel covering portion 21A and the second channel covering portion 21B in a cross-sectional view and in a plan view. That is, the through hole 23 exposes only the drift covering portion 21C.

In this embodiment, the through hole 23 is formed in a band shape extending in the second direction Y in a plan view. That is, the through hole 23 extends in the a-axis direction of the SiC monocrystal. Also, an extension direction of the through hole 23 is matched with the off direction of the SiC monocrystal. In this embodiment, the through hole 23 is formed at an interval inward from both end portions of the planar gate electrode 22 in the second direction Y. The through hole 23 defines the planar gate electrode 22 in a polygonal annular shape (in this embodiment, a square annular shape, specifically a rectangular annular shape) in a plan view.

A planar area of the through hole 23 is preferably greater than one or both of a planar area of the first channel region 13A and a planar area of the second channel region 13B. The planar area of the through hole 23 is particularly preferably greater than a total planar area of the planar area of the first channel region 13A and the planar area of the second channel region 13B.

With reference to FIGS. 4 to 6, the planar gate electrode 22 includes a first electrode portion 22A and a second electrode portion 22B separated from each other by the through hole 23 in a cross-sectional view. The first electrode portion 22A is defined on the first channel covering portion 21A and opposes the first channel region 13A across the first channel covering portion 21A in the vertical direction Z. The first electrode portion 22A is formed in a band shape extending in the second direction Y (the a-axis direction) in a plan view.

The first electrode portion 22A is, on the first channel covering portion 21A, led out toward the first source region 11A side and has a portion opposing the first source region 11A across the first channel covering portion 21A. The first electrode portion 22A is led out from above the first channel covering portion 21A onto the drift covering portion 21C and has a portion opposing the surface layer drift region 14 across the drift covering portion 21C.

The first electrode portion 22A is preferably formed at an interval from the width direction intermediate portion of the drift covering portion 21C toward the first channel covering portion 21A side. That is, a hiding area of the first electrode portion 22A with respect to the drift covering portion 21C is preferably less than the exposed area of the drift covering portion 21C. In the first direction X, a width of the first electrode portion 22A may be less than a width of the through hole 23. As a matter of course, the width of the first electrode portion 22A may be greater than the width of the through hole 23.

The first electrode portion 22A is capacitively coupled to the first source region 11A (the first channel region 13A) across the first channel covering portion 21A and is capacitively coupled to the surface layer drift region 14 across the drift covering portion 21C. The first electrode portion 22A forms a gate-source capacitance Cgs together with the first source region 11A (the first channel region 13A) and forms a gate-drain capacitance Cdg together with the surface layer drift region 14. The gate-drain capacitance Cdg of the first electrode portion 22A is preferably less than the gate-source capacitance Cgs of the first electrode portion 22A.

The second electrode portion 22B is defined on the second channel covering portion 21B at an interval from the first electrode portion 22A in the horizontal direction (the first direction X) and opposes the second channel region 13B across the second channel covering portion 21B in the vertical direction Z. The second electrode portion 22B is formed in a band shape extending in the second direction Y (the a-axis direction) in a plan view. The second electrode portion 22B extends substantially parallel to the first electrode portion 22A in a plan view.

The second electrode portion 22B is, on the second channel covering portion 21B, led out toward the second source region 11B side and has a portion opposing the second source region 11B across the second channel covering portion 21B. The second electrode portion 22B is led out from above the second channel covering portion 21B onto the drift covering portion 21C and has a portion opposing the surface layer drift region 14 across the drift covering portion 21C.

The second electrode portion 22B is preferably formed at an interval from the width direction intermediate portion of the drift covering portion 21C toward the second channel covering portion 21B side. That is, a hiding area of the second electrode portion 22B with respect to the drift covering portion 21C is preferably less than the exposed area of the drift covering portion 21C.

The second electrode portion 22B is capacitively coupled to the second source region 11B (the second channel region 13B) across the second channel covering portion 21B and is capacitively coupled to the surface layer drift region 14 across the drift covering portion 21C. The second electrode portion 22B forms a gate-source capacitance Cgs together with the second source region 11B (the second channel region 13B) and forms a gate-drain capacitance Cdg together with the surface layer drift region 14. The gate-drain capacitance Cdg of the second electrode portion 22B is preferably less than the gate-source capacitance Cgs of the second electrode portion 22B.

In the first direction X, a width of the second electrode portion 22B may be substantially equal to the width of the first electrode portion 22A. The width of the second electrode portion 22B may be less than the width of the first electrode portion 22A. The width of the second electrode portion 22B may be greater than the width of the first electrode portion 22A. The width of the second electrode portion 22B may be less than the width of the through hole 23. The width of the second electrode portion 22B may be greater than the width of the through hole 23.

The second electrode portion 22B does not necessarily have the same conductivity type as the first electrode portion 22A. The conductivity type of the second electrode portion 22B may be the same as the conductivity type of the first electrode portion 22A, or may be different from the conductivity type of the first electrode portion 22A. For example, the first electrode portion 22A may include n-type conductive polysilicon, while the second electrode portion 22B may include p-type conductive polysilicon. For example, the first electrode portion 22A may include p-type conductive polysilicon, while the second electrode portion 22B may include n-type conductive polysilicon.

As a matter of course, when the first electrode portion 22A includes an n-type region and a p-type region formed in the conductive polysilicon in a first layout, the second electrode portion 22B may include the n-type region and the p-type region formed in the conductive polysilicon in a second layout similar to the first layout. As a matter of course, the second layout may be different from the first layout.

Each of the plurality of first planar structures 20A includes an intermediate insulating film 24 that covers the drift covering portion 21C in the through hole 23. The intermediate insulating film 24 may include the same insulating material as the gate insulating film 21, or may include a different insulating material from the gate insulating film 21. The intermediate insulating film 24 may include at least one of a silicon oxide film, a silicon nitride film, and a silicon oxynitride film. In this embodiment, the intermediate insulating film 24 has a single layer structure constituted of a silicon oxide film.

The intermediate insulating film 24 extends in the horizontal direction along the drift covering portion 21C such as to cover the drift covering portion 21C in a film shape and has a portion in contact with a wall surface of the planar gate electrode 22. Specifically, the intermediate insulating film 24 is in contact with a wall surface of the first electrode portion 22A and a wall surface of the second electrode portion 22B in the through hole 23.

The intermediate insulating film 24 is formed at an interval from the first channel region 13A and the second channel region 13B in the horizontal direction. Therefore, the intermediate insulating film 24 opposes the surface layer drift region 14 across the drift covering portion 21C in the vertical direction Z and does not oppose the first channel region 13A and the second channel region 13B in the vertical direction Z.

The intermediate insulating film 24 has a thickness less than a thickness of the planar gate electrode 22 and is formed at an interval from an electrode surface of the planar gate electrode 22 toward the gate insulating film 21 side. The intermediate insulating film 24 may have a thickness greater than a thickness of the gate insulating film 21. The intermediate insulating film 24 may have a thickness less than the thickness of the gate insulating film 21.

Each of the plurality of first planar structures 20A includes a separation insulating film 25 that covers the wall surface of the planar gate electrode 22 in the through hole 23. The separation insulating film 25 may include the same insulating material as the gate insulating film 21, or may include a different insulating material from the gate insulating film 21.

The separation insulating film 25 may include the same insulating material as the intermediate insulating film 24, or may include a different insulating material from the intermediate insulating film 24. The separation insulating film 25 may include at least one of a silicon oxide film, a silicon nitride film, and a silicon oxynitride film. In this embodiment, the separation insulating film 25 has a single layer structure constituted of a silicon oxide film.

The separation insulating film 25 extends in the vertical direction Z along the wall surface of the planar gate electrode 22 and covers the wall surface of the planar gate electrode 22 in a film shape. The separation insulating film 25 is arranged on the drift covering portion 21C and has a portion opposing the surface layer drift region 14 across the drift covering portion 21C in the vertical direction Z. The separation insulating film 25 is connected to the gate insulating film 21 (the drift covering portion 21C) and the intermediate insulating film 24 on a lower end side of the planar gate electrode 22.

Specifically, the separation insulating film 25 extends in the vertical direction Z along the wall surface of the first electrode portion 22A in a cross-sectional view and covers the wall surface of the first electrode portion 22A in a film shape. The separation insulating film 25 is connected to the gate insulating film 21 (the drift covering portion 21C) and the intermediate insulating film 24 on a lower end side of the first electrode portion 22A. That is, the separation insulating film 25 is formed at an interval from the first channel region 13A in the horizontal direction and does not oppose the first channel region 13A in the vertical direction Z.

The separation insulating film 25 extends in the vertical direction Z along the wall surface of the second electrode portion 22B in a cross-sectional view and covers the wall surface of the second electrode portion 22B in a film shape. The separation insulating film 25 is connected to the gate insulating film 21 (the drift covering portion 21C) and the intermediate insulating film 24 on a lower end side of the second electrode portion 22B. That is, the separation insulating film 25 is formed at an interval from the second channel region 13B in the horizontal direction and does not oppose the second channel region 13B in the vertical direction Z.

The separation insulating film 25 defines an insulating recess 26 together with the intermediate insulating film 24 in the through hole 23. The insulating recess 26 is formed in a band shape extending along the through hole 23 in a plan view. The insulating recess 26 is formed to be narrower than the surface layer drift region 14 in a cross-sectional view.

The separation insulating film 25 may have a thickness greater than the thickness of the gate insulating film 21. The thickness of the separation insulating film 25 is defined as a thickness in the horizontal direction with respect to the wall surface of the planar gate electrode 22. The thickness of the separation insulating film 25 may be less than the thickness of the gate insulating film 21. The thickness of the separation insulating film 25 may be greater than the thickness of the intermediate insulating film 24. The thickness of the separation insulating film 25 may be less than the thickness of the intermediate insulating film 24. The thickness of the separation insulating film 25 may be less than the thickness of the planar gate electrode 22. The thickness of the separation insulating film 25 may be greater than the thickness of the planar gate electrode 22.

Each of the plurality of first planar structures 20A includes a planar insulating film 27 that covers the planar gate electrode 22. The planar insulating film 27 may include the same insulating material as the gate insulating film 21, or may include a different insulating material from the gate insulating film 21. The planar insulating film 27 may include the same insulating material as the intermediate insulating film 24, or may include a different insulating material from the intermediate insulating film 24.

The planar insulating film 27 may include the same insulating material as the separation insulating film 25, or may include a different insulating material from the separation insulating film 25. The planar insulating film 27 may include at least one of a silicon oxide film, a silicon nitride film, and a silicon oxynitride film. In this embodiment, the planar insulating film 27 has a single layer structure constituted of a silicon oxide film.

The planar insulating film 27 covers the electrode surface of the planar gate electrode 22 from above the gate insulating film 21 through the wall surface of the planar gate electrode 22. Specifically, the planar insulating film 27 covers an electrode surface of the first electrode portion 22A from above the first channel covering portion 21A through the wall surface of the first electrode portion 22A and covers an electrode surface of the second electrode portion 22B from above the second channel covering portion 21B through the wall surface of the second electrode portion 22B.

The planar insulating film 27 has a portion extending in a film shape in the horizontal direction along the first channel covering portion 21A, a portion extending in a film shape in the horizontal direction along the second channel covering portion 21B, a portion extending in a film shape in the horizontal direction along the first electrode portion 22A, and a portion extending in a film shape in the horizontal direction along the second electrode portion 22B. A portion of the planar insulating film 27 which covers the first electrode portion 22A and the second electrode portion 22B is positioned above a portion of the planar insulating film 27 which covers the first channel covering portion 21A and the second channel covering portion 21B.

The planar insulating film 27 is connected to the separation insulating film 25 in the inner portion of the planar gate electrode 22 and defines a recess through hole 28 communicating with the insulating recess 26. The recess through hole 28 is formed in a band shape extending along the insulating recess 26 in a plan view. In this embodiment, the recess through hole 28 is formed to be narrower than the surface layer drift region 14 in a cross-sectional view.

In this embodiment, the intermediate insulating film 24 and the separation insulating film 25 are constituted of a part of the planar insulating film 27, and the insulating recess 26 and the recess through hole 28 are formed by an etching processing method for the planar insulating film 27 (a portion covering the through hole 23). Therefore, the recess through hole 28 has a wall surface flush with a wall surface of the insulating recess 26. A width of the recess through hole 28 is substantially equal to a width of the insulating recess 26.

Each of the plurality of first planar structures 20A includes a planar source electrode 29 arranged over the gate insulating film 21. The planar source electrode 29 is arranged over the drift covering portion 21C at an interval from the planar gate electrode 22 such as to oppose the planar gate electrode 22 in the horizontal direction and opposes the surface layer drift region 14 across the drift covering portion 21C in the vertical direction Z.

Specifically, the planar source electrode 29 is arranged in the insulating recess 26. The planar source electrode 29 is formed in a band shape extending in the second direction Y along the insulating recess 26 in a plan view. That is, the planar source electrode 29 extends in the a-axis direction of the SiC monocrystal. Also, an extension direction of the planar source electrode 29 is matched with the off direction of the SiC monocrystal.

The planar source electrode 29 opposes the planar gate electrode 22 across the separation insulating film 25 in the horizontal direction in the insulating recess 26 and is electrically insulated from the planar gate electrode 22 by the separation insulating film 25. Specifically, the planar source electrode 29 opposes both the first electrode portion 22A and the second electrode portion 22B across the separation insulating film 25 in the horizontal direction in a cross-sectional view and is electrically insulated from both the first electrode portion 22A and the second electrode portion 22B by the separation insulating film 25.

In this embodiment, the planar source electrode 29 protrudes from the insulating recess 26 toward the recess through hole 28 side and has a portion positioned in the recess through hole 28. That is, the planar source electrode 29 has a portion positioned below the electrode surface (an upper end portion) of the planar gate electrode 22 (on the gate insulating film 21 side) and a portion positioned above the electrode surface (the upper end portion) of the planar gate electrode 22 (on the side opposite to the gate insulating film 21).

The planar source electrode 29 has a portion in contact with the intermediate insulating film 24 and the separation insulating film 25 in the insulating recess 26 and has a portion in contact with the planar insulating film 27 in the recess through hole 28. That is, the planar source electrode 29 opposes the surface layer drift region 14 across the intermediate insulating film 24 and the gate insulating film 21 in the vertical direction Z in the insulating recess 26. A height position of a lower end of the planar source electrode 29 is positioned above a height position of the lower end of the planar gate electrode 22.

The planar source electrode 29 is capacitively coupled to the surface layer drift region 14 via the gate insulating film 21. Specifically, the planar source electrode 29 is capacitively coupled to the surface layer drift region 14 via the intermediate insulating film 24 and the gate insulating film 21. The planar source electrode 29 forms a drain-source capacitance Cds together with the surface layer drift region 14 and reduces a feedback capacitance Crss (=the gate-drain capacitance Cdg) between the surface layer drift region 14 and the planar gate electrode 22. As a result, a switching speed is improved.

In the first planar structure 20A, the planar gate electrode 22 and the planar source electrode 29 are adjacent to each other in the horizontal direction and arranged over the same gate insulating film 21, and the planar source electrode 29 opposes the surface layer drift region 14 across the gate insulating film 21. Therefore, since the source potential is generated in the vicinity of a lateral side of the planar gate electrode 22, the electrical influence of the gate potential on the surface layer drift region 14 is reduced. This prevents the planar gate electrode 22 from being capacitively coupled to the surface layer drift region 14 via the gate insulating film 21.

The planar source electrode 29 includes a different conductive material from the planar gate electrode 22. Specifically, the planar source electrode 29 includes a metal. More specifically, the planar source electrode 29 includes a metal base electrode film 30 and a metal electrode main body 31.

The base electrode film 30 is constituted of a metal barrier film. The base electrode film 30 includes at least one of a Ti film, a TiN film, and a W film. In this embodiment, the base electrode film 30 includes a Ti film. The base electrode film 30 is formed in a film shape along a wall surface of the insulating recess 26 and the wall surface of the recess through hole 28.

The base electrode film 30 has a portion that covers the intermediate insulating film 24 and the separation insulating film 25 in the insulating recess 26. The base electrode film 30 covers the planar insulating film 27 in the recess through hole 28. The base electrode film 30 has a thickness less than ½ of a width of the insulating recess 26 and defines an electrode recess in the insulating recess 26 and the recess through hole 28.

The electrode main body 31 forms a body of the planar source electrode 29. The electrode main body 31 includes at least one type among a pure W film (a W film having a purity of 99% or more), a W alloy film, an Al film, a Cu film, an Al alloy film, and a Cu alloy film. The electrode main body 31 may include at least one of a pure Cu film (a Cu film having a purity of 99% or more), a pure Al film (an Al film having a purity of 99% or more), an AlCu alloy film, an AlSi alloy film, and an AlSiCu alloy film. In this embodiment, the electrode main body 31 includes an Al alloy film (in this embodiment, an AlSiCu alloy film).

The electrode main body 31 has a thickness greater than the thickness of the base electrode film 30 and is embedded in the insulating recess 26 and the recess through hole 28 across the base electrode film 30. The electrode main body 31 has a portion opposing the insulating recess 26 across the base electrode film 30 and a portion opposing the recess through hole 28 across the base electrode film 30.

The electrode main body 31 has a portion that covers the intermediate insulating film 24 and the separation insulating film 25 across the base electrode film 30 in the insulating recess 26. The electrode main body 31 has a portion that covers the planar insulating film 27 across the base electrode film 30 in the recess through hole 28.

The SiC semiconductor device 1A includes a plurality of contact recesses 32 formed in regions between the plurality of first planar structures 20A (a plurality of planar insulating films 27) adjacent to each other on the first main surface 3. In this embodiment, the plurality of contact recesses 32 are arranged at intervals in the first direction X and are each formed in a band shape extending in the second direction Y.

That is, the plurality of contact recesses 32 are alternately formed with the plurality of first planar structures 20A in the first direction X. Also, the plurality of contact recesses 32 are arranged at intervals in the m-axis direction of the SiC monocrystal and extend in the a-axis direction of the SiC monocrystal. Also, the plurality of contact recesses 32 are formed in a stripe shape extending in the second direction Y (the a-axis direction).

The plurality of contact recesses 32 are formed in the surface layer portions of the plurality of body regions 10 such as to expose the plurality of contact regions 12 in a one-to-one correspondence relationship. Each contact recess 32 has a bottom wall positioned on the bottom portion side of the body region 10 with respect to a height position of the gate insulating film 21. Each contact recess 32 is formed at an interval inward from the peripheral edge of the body region 10 and is formed in a horizontally long recess shape extending at an interval from a bottom portion of the contact region 12 toward the first main surface 3 side in the horizontal direction.

Each contact recess 32 is led out from the contact region 12 toward the peripheral edge side of the body region 10 and partially exposes both the first source region 11A and the second source region 11B from both sides. The bottom wall of each contact recess 32 is formed at an interval from a bottom portion of the first source region 11A and a bottom portion of the second source region 11B toward the first main surface 3 side. The contact recess 32 is not necessarily formed, and a configuration not having the contact recess 32 may be adopted.

With reference to FIG. 2, the SiC semiconductor device 1A includes an interlayer insulating film 40 that selectively covers the first main surface 3. In this embodiment, the interlayer insulating film 40 has a laminated structure including a first insulating film 41 and a second insulating film 42. The first insulating film 41 may include at least one of a silicon oxide film, a silicon nitride film, and a silicon oxynitride film. The first insulating film 41 particularly preferably includes the silicon oxide film that is constituted of the oxide of the chip 2.

The first insulating film 41 selectively covers the first main surface 3 in the active region 8 and the outer peripheral region 9. Specifically, the first insulating film 41 covers a region outside the plurality of gate insulating films 21 in the active region 8 and is connected to the plurality of gate insulating films 21. In this embodiment, the first insulating film 41 is formed integrally with the plurality of gate insulating films 21 and forms one insulating film together with the plurality of gate insulating films 21.

The first insulating film 41 covers the first main surface 3 such as to be continuous to a peripheral edge (the first to fourth side surfaces 5A to 5D) of the first main surface 3 in the outer peripheral region 9. As a matter of course, the first insulating film 41 may be formed at an interval inward from the peripheral edge of the first main surface 3 and expose the drift region 6 from a peripheral edge potion of the first main surface 3.

The second insulating film 42 is laminated on the first insulating film 41. The second insulating film 42 may include at least one of a silicon oxide film, a silicon nitride film, and a silicon oxynitride film. The interlayer insulating film 40 preferably includes a silicon oxide film.

The second insulating film 42 selectively covers the first main surface 3 in the active region 8 and the outer peripheral region 9 across the first insulating film 41. Specifically, the second insulating film 42 covers a region outside the plurality of planar insulating films 27 in the active region 8 and is connected to the plurality of planar insulating films 27. In this embodiment, the second insulating film 42 is formed integrally with the plurality of planar insulating films 27 and forms one insulating film together with the plurality of planar insulating films 27.

The second insulating film 42 covers the first insulating film 41 such as to be continuous to the peripheral edge (the first to fourth side surfaces 5A to 5D) of the first main surface 3 in the outer peripheral region 9. As a matter of course, the second insulating film 42 may be formed at an interval inward from the peripheral edge of the first main surface 3 and expose the drift region 6 from the peripheral edge potion of the first main surface 3.

With reference to FIG. 4, although a specific cross-sectional view is omitted, the SiC semiconductor device 1A includes a plurality of gate openings 43 that expose the plurality of planar gate electrodes 22. The plurality of gate openings 43 pass through the plurality of planar insulating films 27 and expose one or both of one end portions and the other end portions (in this embodiment, both end portions) of the plurality of planar gate electrodes 22. The plurality of gate openings 43 may expose one or both of one end portions and the other end portions of the plurality of first electrode portions 22A. The plurality of gate openings 43 may expose one or both of one end portions and the other end portions of the plurality of second electrode portions 22B.

The SiC semiconductor device 1A includes a plurality of source openings 44 each formed in a region between the plurality of first planar structures 20A (the plurality of planar insulating films 27). The plurality of source openings 44 pass through the gate insulating film 21 and the planar insulating film 27 and expose the plurality of contact recesses 32 in a one-to-one correspondence relationship.

That is, each source opening 44 exposes the first source region 11A, the second source region 11B, and the contact region 12 through the corresponding contact recess 32. In this embodiment, each source opening 44 also exposes the corresponding planar insulating film 27 and gate insulating film 21.

In this embodiment, the source opening 44 is formed in a band shape extending in the second direction Y along the contact recess 32 in a plan view. That is, the source opening 44 extends in the a-axis direction of the SiC monocrystal. Also, an extension direction of the source opening 44 is matched with the off direction of the SiC monocrystal. As a matter of course, the plurality of source openings 44 may be formed at intervals in the second direction Y.

With reference to FIGS. 1 to 6, the SiC semiconductor device 1A includes a first main surface electrode 45 that is arranged on the interlayer insulating film 40. The first main surface electrode 45 has a laminated structure including a base electrode film 46 and an electrode main body film 47 laminated in that order from the interlayer insulating film 40 side. The base electrode film 46 is constituted of a metal barrier film and is laminated on the interlayer insulating film 40.

The base electrode film 46 includes at least one of a Ti film, a TiN film, and a W film. In this embodiment, the base electrode film 46 includes a Ti film. The base electrode film 46 is formed in a film shape along a wall surface of the interlayer insulating film 40.

The electrode main body film 47 has a thickness larger than a thickness of the base electrode film 46 and is laminated on the base electrode film 46. The electrode main body film 47 includes at least one type among a pure W film (a W film having a purity of 99% or more), a W alloy film, an Al film, a Cu film, an Al alloy film, and a Cu alloy film. The electrode main body film 47 may include at least one of a pure Cu film (a Cu film having a purity of 99% or more), a pure Al film (an Al film having a purity of 99% or more), an AlCu alloy film, an AlSi alloy film, and an AlSiCu alloy film. In this embodiment, the electrode main body film 47 includes an Al alloy film (in this embodiment, an AlSiCu alloy film).

With reference to FIGS. 1 and 2, the first main surface electrode 45 includes a gate pad 48 arranged on the interlayer insulating film 40. The gate pad 48 is an electrode to which a gate potential is applied from the outside. The gate pad 48 may be referred to as a “gate pad electrode,” a “first pad electrode,” etc. In this embodiment, the gate pad 48 is arranged on a portion of the interlayer insulating film 40 which covers the active region 8. In this embodiment, the gate pad 48 is formed in a polygonal shape (in this embodiment, a quadrangle shape) in a plan view.

The gate pad 48 may be arranged in the active region 8 at an interval from the outer peripheral region 9 in a plan view. As a matter of course, the gate pad 48 may have a portion that is led out from the active region 8 to the outer peripheral region 9 and positioned in the outer peripheral region 9. In this embodiment, the gate pad 48 is arranged in a peripheral edge potion of the active region 8 in a plan view.

FIG. 1 illustrates an example in which the gate pad 48 is arranged in a region along a central portion of the second side surface 5B in the peripheral edge potion of the active region 8. As a matter of course, the gate pad 48 may be arranged in a region along any of central portions of the first to fourth side surfaces 5A to 5D. The gate pad 48 may be arranged at any corner potion of the active region 8 in a plan view. The gate pad 48 may be arranged at the central portion of the active region 8 in a plan view.

With reference to FIGS. 1 and 4, the first main surface electrode 45 includes at least one gate wiring 49A, 49B (in this embodiment, a plurality of gate wirings 49A, 49B) led out from the gate pad 48 onto the interlayer insulating film 40 (the plurality of planar insulating films 27). The gate wiring 49A, 49B may be referred to as a “wiring,” a “wiring electrode,” etc.

The plurality of gate wirings 49A, 49B include a first gate wiring 49A and a second gate wiring 49B. The first gate wiring 49A is led out from the gate pad 48 toward the first side surface 5A side and extends linearly along a peripheral edge of the active region 8 such as to intersect with (specifically, to be orthogonal to) parts (specifically, one end portions) of the plurality of first planar structures 20A. That is, the first gate wiring 49A covers the plurality of planar insulating films 27.

The first gate wiring 49A passes through the plurality of planar insulating films 27 through the plurality of gate openings 43 and is electrically connected to one end portions of the plurality of planar gate electrodes 22 (the first electrode portion 22A and the second electrode portion 22B). The first gate wiring 49A is formed at an interval from one end portion of the planar source electrode 29 toward the peripheral edge side of the chip 2 in a plan view and opposes the planar source electrode 29 in the second direction Y.

That is, the first gate wiring 49A does not oppose the planar source electrode 29 across the planar insulating film 27. As a matter of course, the first gate wiring 49A may oppose the one end portion of the planar source electrode 29 across the planar insulating film 27 and may be electrically insulated from the planar source electrode 29 by the planar insulating film 27.

On the other hand, the second gate wiring 49B is led out from the gate pad 48 toward the third side surface 5C side and extends linearly along the peripheral edge of the active region 8 such as to intersect with (specifically, to be orthogonal to) parts (specifically, the other end portions) of the plurality of first planar structures 20A. That is, the second gate wiring 49B covers the plurality of planar insulating films 27.

The second gate wiring 49B passes through the plurality of planar insulating films 27 through the plurality of gate openings 43 and is electrically connected to the other end portions of the plurality of planar gate electrodes 22 (the first electrode portion 22A and the second electrode portion 22B). The second gate wiring 49B is formed at an interval from the other end portion of the planar source electrode 29 toward the peripheral edge side of the chip 2 in a plan view and opposes the planar source electrode 29 in the second direction Y.

That is, the second gate wiring 49B does not oppose the planar source electrode 29 across the planar insulating film 27. As a matter of course, the second gate wiring 49B may oppose the other end portion of the planar source electrode 29 across the planar insulating film 27 and may be electrically insulated from the planar source electrode 29 by the planar insulating film 27.

With reference to FIGS. 1, 2, 5, and 6, the first main surface electrode 45 includes a source pad 50 arranged on the interlayer insulating film 40 (the plurality of planar insulating films 27) at an interval from the gate pad 48 and the gate wirings 49A, 49B. The source pad 50 is an electrode to which a source potential is applied from the outside. The source pad 50 may be referred to as a “source pad electrode,” a “second pad electrode,” etc.

The source pad 50 covers the plurality of planar insulating films 27 in the active region 8. The source pad 50 may be arranged in the active region 8 at an interval from the outer peripheral region 9. As a matter of course, the source pad 50 may have a portion that is led out from the active region 8 to the outer peripheral region 9 and positioned in the outer peripheral region 9. In this embodiment, the source pad 50 is formed in a polygonal shape having a recess portion that is recessed along the gate pad 48 in plan view. As a matter of course, the source pad 50 may be formed in a quadrangle shape in a plan view.

The source pad 50 passes through the plurality of planar insulating films 27 and the plurality of gate insulating films 21 through the plurality of source openings 44 and is electrically connected to the plurality of first source regions 11A, the plurality of second source regions 11B, and the plurality of contact regions 12. The source pad 50 is electrically connected to the plurality of body regions 10 via the plurality of first source regions 11A, the plurality of second source regions 11B, and the plurality of contact regions 12.

The base electrode film 46 of the source pad 50 enters into the contact recess 32 from above the planar insulating film 27 through the source opening 44 and is electrically connected to the plurality of first source regions 11A, the plurality of second source regions 11B, and the plurality of contact regions 12 in the contact recess 32.

The electrode main body film 47 of the source pad 50 enters into the contact recess 32 from above the base electrode film 46 through the source opening 44 and is electrically connected to the plurality of first source regions 11A, the plurality of second source regions 11B, and the plurality of contact regions 12 via the base electrode film 46.

When the thickness of the base electrode film 46 is less than a depth of the contact recess 32, the electrode main body film 47 of the source pad 50 is connected to the base electrode film 46 in the contact recess 32. When the thickness of the base electrode film 46 is greater than the depth of the contact recess 32, the electrode main body film 47 of the source pad 50 is connected to the base electrode film 46 in the source opening 44.

In this embodiment, the source pad 50 is electrically connected to the plurality of planar source electrodes 29 on the plurality of planar insulating films 27. In this embodiment, the source pad 50 includes the plurality of planar source electrodes 29. That is, the plurality of planar source electrodes 29 enter into a plurality of insulating recesses 26 through a plurality of recess through holes 28 from above the plurality of planar insulating films 27 and form the plurality of planar source electrodes 29 in the plurality of insulating recesses 26 (the plurality of recess through holes 28).

Specifically, the base electrode film 46 of the source pad 50 enters into the insulating recess 26 from above the planar insulating films 27 through the recess through hole 28 and forms the base electrode film 30 of the planar source electrode 29 in the insulating recess 26 and the recess through hole 28. The electrode main body film 47 of the source pad 50 enters into the insulating recess 26 from above the base electrode film 46 through the recess through hole 28 and forms the electrode main body 31 of the planar source electrode 29 in the insulating recess 26 and the recess through hole 28.

The SiC semiconductor device 1A includes a drain pad 51 as a second main surface electrode covering the second main surface 4. The drain pad 51 is an electrode to which a drain potential is applied from the outside. The drain pad 51 may be referred to as a “drain pad electrode,” a “third pad electrode,” etc. The drain pad 51 forms an ohmic contact with the drain region 7 exposed from the second main surface 4.

That is, the drain pad 51 is electrically connected to the drift region 6 and the surface layer drift region 14 via the drain region 7. The drain pad 51 may cover an entire region of the second main surface 4 such as to be continuous to the peripheral edge (the first to fourth side surfaces 5A to 5D) of the chip 2. The drain pad 51 may cover the second main surface 4 at an interval inward from the peripheral edge of the chip 2 such as to expose a peripheral edge portion of the chip 2.

A breakdown voltage that can be applied between the source pad 50 and the drain pad 51 (between the first main surface 3 and the second main surface 4) may be not less than 500 V and not more than 3000 V. The breakdown voltage may have a value belonging to any one range of not less than 500 V and not more than 1000 V, not less than 1000 V and not more than 1500 V, not less than 1500 V and not more than 2000 V, not less than 2000 V and not more than 2500 V, and not less than 2500 V and not more than 3000 V.

Hereinafter, second to eleventh configuration examples of the first planar structure 20A will be described. The first planar structure 20A may have one or more of the features of the second to eleventh configuration examples instead of or in addition to the feature of the first configuration example. That is, the first planar structure 20A may have at least one feature of the first to eleventh configuration examples.

Also, the first planar structure 20A may have a feature in which a plurality of features of the first to eleventh configuration examples are combined. Also, the first planar structure 20A may partially have one or more features of the first to eleventh configuration examples in a different region. The SiC semiconductor device 1A may simultaneously include, in the active region 8, at least two first planar structures 20A of the first planar structures 20A according to the first to eleventh configuration examples.

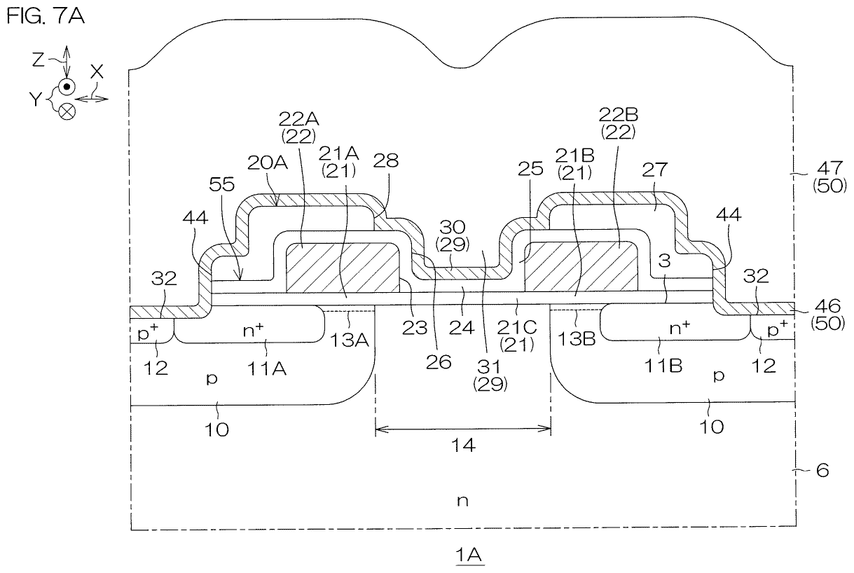

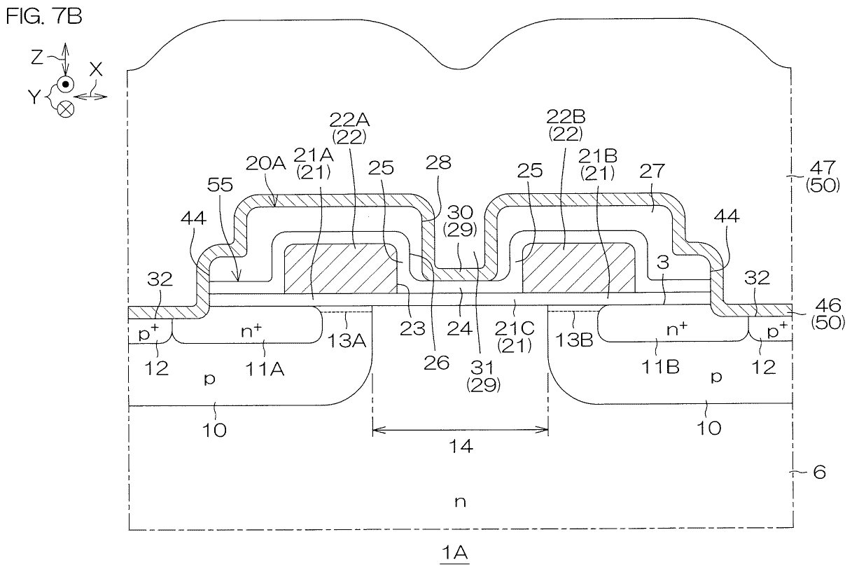

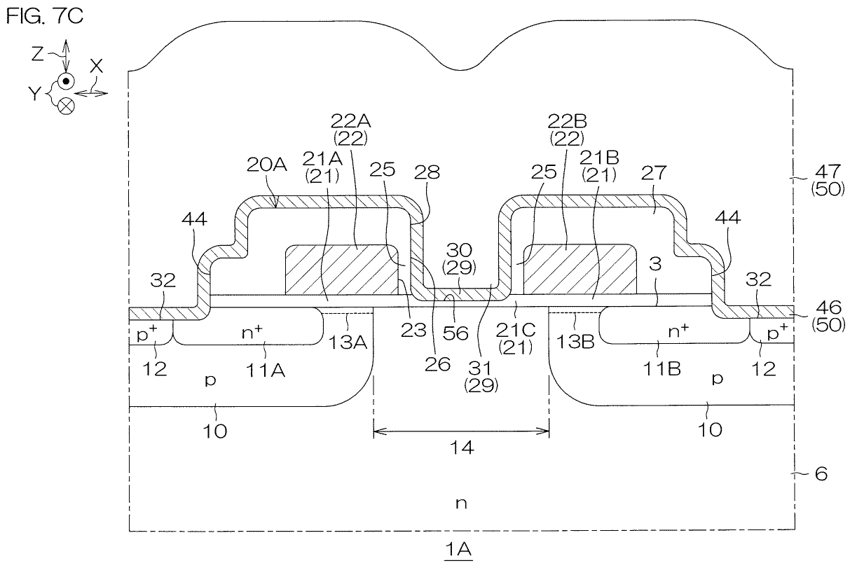

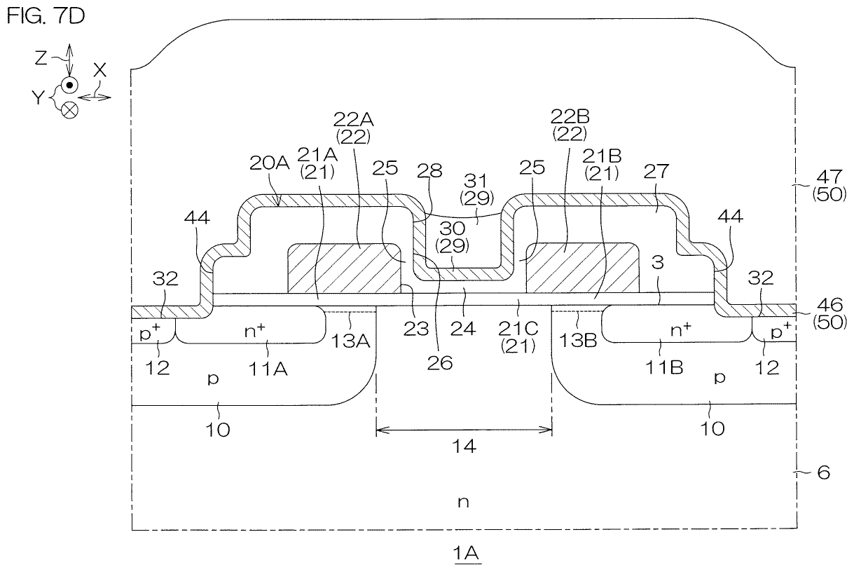

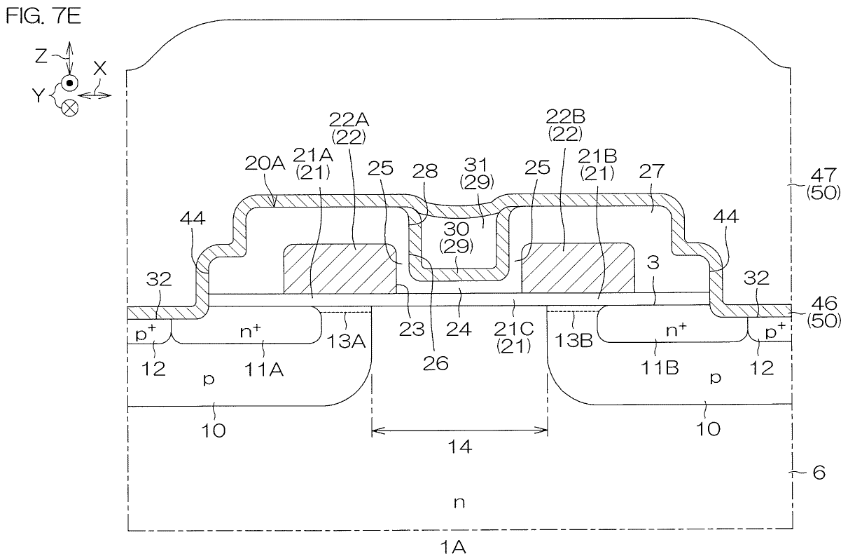

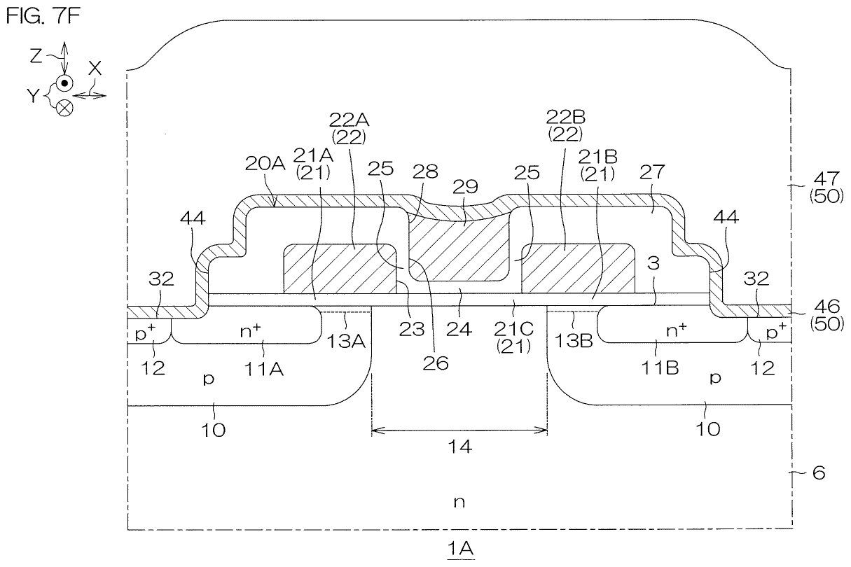

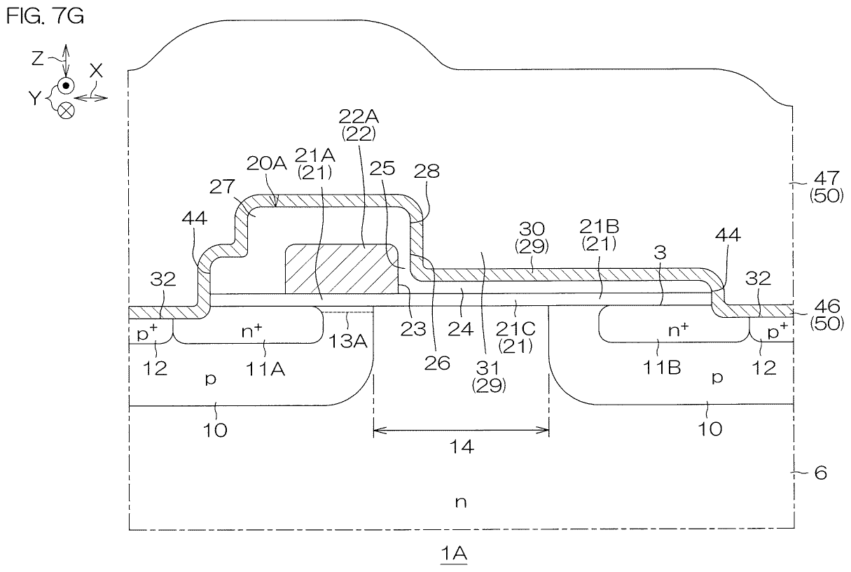

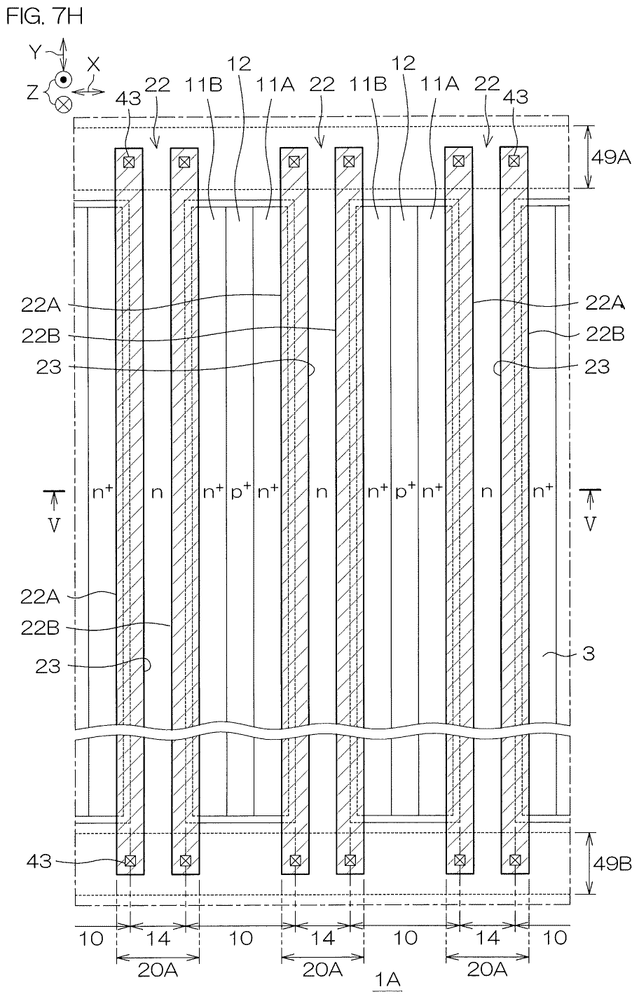

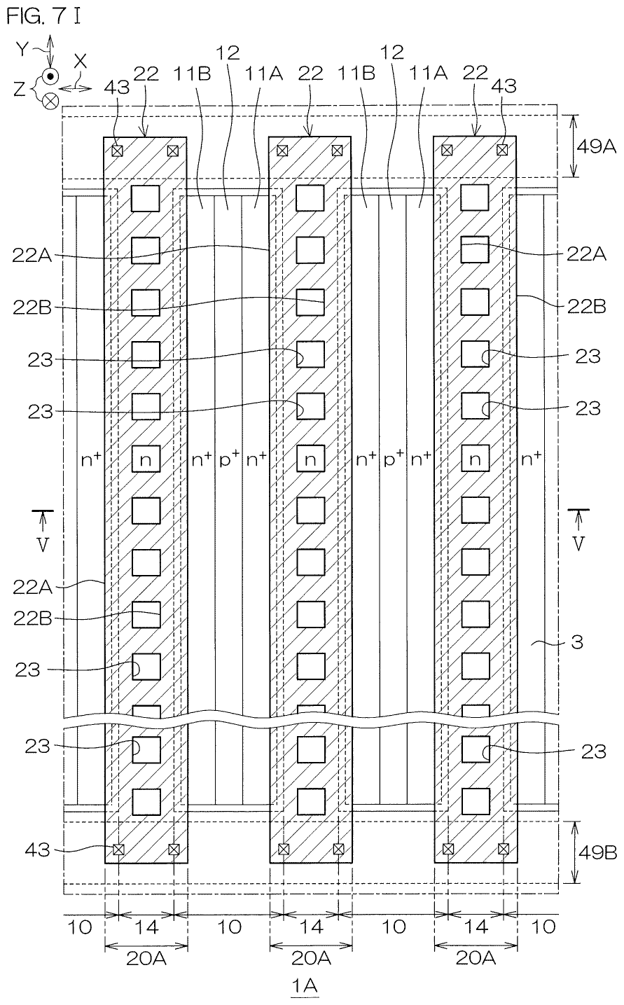

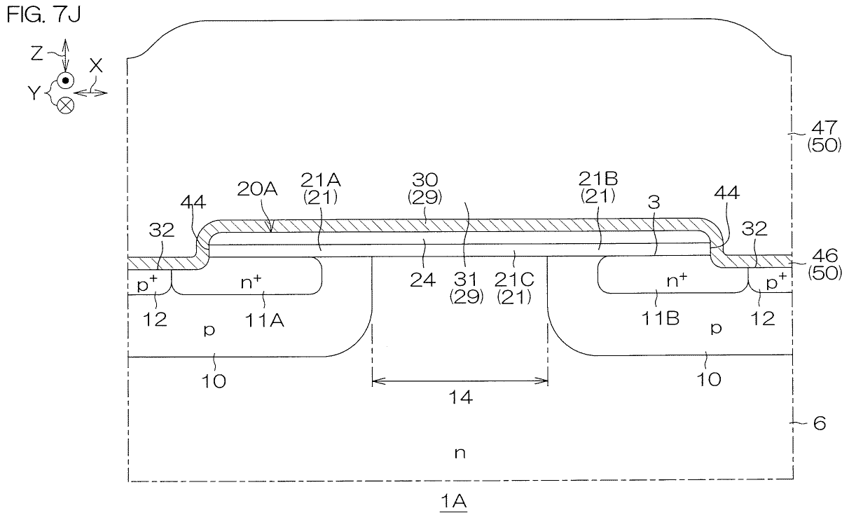

FIG. 7A is an enlarged cross-sectional view showing the first planar structure 20A according to the second configuration example. In the first configuration example described above, an example in which the intermediate insulating film 24, the separation insulating film 25, and the planar insulating film 27 are formed of the same insulating film has been described. On the other hand, the first planar structure 20A according to the second configuration example has an insulating film 55 that includes the intermediate insulating film 24 and the separation insulating film 25 integrally with each other and is separately constituted of the planar insulating film 27.

The insulating film 55 as an etching stopper film is formed of a different insulating material from the planar insulating film 27. For example, the insulating film 55 may be formed of a silicon nitride film, and the planar insulating film 27 may be formed of a silicon oxide film. As a matter of course, the insulating film 55 may be formed of a silicon oxide film, and the planar insulating film 27 may be formed of a silicon nitride film.

In this example, the insulating film 55 (the separation insulating film 25) is led out from the through hole 23 onto the electrode surface of the planar gate electrode 22 and is led out onto each of the first channel covering portion 21A and the second channel covering portion 21B through the wall surface of the planar gate electrode 22. That is, the insulating film 55 (the separation insulating film 25) covers the gate insulating film 21 and the planar gate electrode 22 (the first electrode portion 22A and the second electrode portion 22B) in a film shape and defines the insulating recess 26 in the through hole 23.

According to the insulating film 55 (the separation insulating film 25), the restriction on the layout (the width or the planar shape) of the recess through hole 28 caused by the layout (the width or the planar shape) of the insulating recess 26 is relaxed. For example, the planar insulating film 27 may cover the gate insulating film 21 and the planar gate electrode 22 (the first electrode portion 22A and the second electrode portion 22B) across the insulating film 55 (the separation insulating film 25) such as to expose an entire region of the insulating recess 26.

The planar insulating film 27 may have the recess through hole 28 that covers the insulating film 55 (the separation insulating film 25) at an interval outward from the wall surface of insulating recess 26 and exposes the entire region of the insulating recess 26. In this case, the width of the recess through hole 28 may be greater than the width of the insulating recess 26.

FIG. 7B is an enlarged cross-sectional view showing the first planar structure 20A according to the third configuration example. The first planar structure 20A according to the third configuration example has a form obtained by modifying the first planar structure 20A according to the second configuration example. In the third configuration example, the planar insulating film 27 covers the gate insulating film 21 and the planar gate electrode 22 (the first electrode portion 22A and the second electrode portion 22B) across the insulating film 55 (the separation insulating film 25) such as to partially expose the insulating recess 26.

The planar insulating film 27 enters into the insulating recess 26 from above the insulating film 55 and has a portion covering the intermediate insulating film 24 and a portion covering the separation insulating film 25 in the insulating recess 26. The planar insulating film 27 defines the recess through hole 28 that partially exposes the intermediate insulating film 24 in the insulating recess 26. In this case, the width of the recess through hole 28 may be less than the width of the insulating recess 26.

FIG. 7C is an enlarged cross-sectional view showing the first planar structure 20A according to the fourth configuration example. The feature according to the fourth configuration example is also applicable to any one or more of the first to third configuration examples. In the first configuration example, the intermediate insulating film 24 that covers the drift covering portion 21C is formed in the through hole 23. On the other hand, the first planar structure 20A according to the fourth configuration example has the separation insulating film 25 but does not have the intermediate insulating film 24.

Such a configuration is formed by completely removing the intermediate insulating film 24 by an etching method. The intermediate insulating film 24 may be constituted of the same insulating material as the gate insulating film 21, or may be constituted of a different insulating material from the gate insulating film 21.

When the insulating material of the intermediate insulating film 24 is the same as the insulating material of the gate insulating film 21, strict etching processing conditions are imposed in order to avoid the disappearance of the gate insulating film 21 due to the etching processing of the intermediate insulating film 24. When the insulating material of the intermediate insulating film 24 is different from the insulating material of the gate insulating film 21, the gate insulating film 21 functions as an etching stopper film for etching processing of the intermediate insulating film 24. In these cases, the planar insulating film 27 may be constituted of the same insulating material (the same insulating film) as the intermediate insulating film 24, or may be constituted of a different insulating material (a different insulating film) from the intermediate insulating film 24.

The first planar structure 20A may have a recess portion 56 recessed toward the surface layer drift region 14 in a portion (the insulating recess 26) of the drift covering portion 21C which is exposed from the separation insulating film 25. The recess portion 56 is constituted of a thinned portion of the drift covering portion 21C. That is, the recess portion 56 has a bottom portion positioned closer to the first main surface 3 than a portion of the drift covering portion 21C hidden by the separation insulating film 25.

The bottom portion of the recess portion 56 is positioned closer to the first main surface 3 than an upper end of the first channel covering portion 21A and an upper end of the second channel covering portion 21B. The recess portion 56 is not necessarily formed, and a configuration not having the recess portion 56 may be adopted. In this case, a height position of a portion of the drift covering portion 21C which is exposed from the insulating recess 26 is substantially equal to a height position of other portions.

The planar source electrode 29 is arranged on the recess portion 56 in the insulating recess 26 and opposes the surface layer drift region 14 across the thinned portion of the drift covering portion 21C in the vertical direction Z. The height position of the lower end of the planar source electrode 29 is positioned below the height position of the lower end of the planar gate electrode 22.

The base electrode film 30 of the planar source electrode 29 is formed in a film shape along a wall surface of the recess portion 56, a wall surface of the insulating recess 26, and the wall surface of the recess through hole 28 and covers the thinned portion of the drift covering portion 21C, the separation insulating film 25, and the planar insulating film 27. It is preferable that base electrode film 30 has a thickness greater than a depth of the recess portion 56 and has an electrode surface positioned above the recess portion 56.

That is, the electrode surface of the base electrode film 30 is positioned above the upper end of the first channel covering portion 21A and the upper end of the second channel covering portion 21B. As a matter of course, the base electrode film 30 may have a thickness less than the depth of the recess portion 56 and have an electrode surface positioned below the recess portion 56.

The electrode main body 31 of the planar source electrode 29 is embedded in the insulating recess 26 and the recess through hole 28 through the base electrode film 30. The electrode main body 31 has a portion opposing the recess portion 56 through the base electrode film 30, a portion opposing the insulating recess 26 through the base electrode film 30, and a portion opposing the recess through hole 28 through the base electrode film 30. That is, the electrode main body 31 has a portion that covers the thinned portion of the drift covering portion 21C through the base electrode film 30.

When the thickness of the base electrode film 30 is greater than the depth of the recess portion 56, the electrode main body 31 is connected to the base electrode film 30 in the insulating recess 26. When the thickness of the base electrode film 30 is less than the depth of the recess portion 56, the electrode main body 31 is connected to the base electrode film 30 in the recess portion 56.

The planar source electrode 29 is capacitively coupled to the surface layer drift region 14 across the thinned portion of the drift covering portion 21C. The planar source electrode 29 forms a drain-source capacitance Cds together with the surface layer drift region 14 and reduces a feedback capacitance Crss (=the gate-drain capacitance Cdg) between the surface layer drift region 14 and the planar gate electrode 22.

FIG. 7D is an enlarged cross-sectional view showing the first planar structure 20A according to the fifth configuration example. The feature according to the fifth configuration example is also applicable to any one or more of the first to fourth configuration examples. In the first configuration example described above, the electrode main body 31 of the planar source electrode 29 is formed of a part of the electrode main body film 47 of the source pad 50. On the other hand, in the fifth configuration example, the electrode main body 31 is formed separately from the electrode main body film 47.

The electrode main body 31 may include at least one type among a pure W film (a W film having a purity of 99% or more), a W alloy film, an Al film, a Cu film, an Al alloy film, and a Cu alloy film as in the case of the first configuration example. The electrode main body 31 is preferably constituted of the pure W film or the W alloy film among these metal types. That is, the electrode main body 31 of the planar source electrode 29 is preferably formed as a tungsten plug electrode.

An electrode surface of the planar source electrode 29 is positioned on the gate insulating film 21 (the drift covering portion 21C) side with respect to a main surface of the planar insulating film 27 and is exposed from the insulating recess 26 (the recess through hole 28). The electrode surface of the planar source electrode 29 may be recessed toward the gate insulating film 21 (the drift covering portion 21C) side. In this example, the electrode surface of the planar source electrode 29 is recessed in a curved shape toward the gate insulating film 21 (the drift covering portion 21C) side.

The base electrode film 46 of the source pad 50 is integrally formed with the base electrode film 30 of the planar source electrode 29 as in the case of the first configuration example. The electrode main body film 47 of the source pad 50 directly covers the electrode main body 31 and is physically and electrically connected to the electrode main body 31. The electrode main body film 47 is connected to the electrode surface of the planar source electrode 29 on the drift covering portion 21C side with respect to the main surface of the planar insulating film 27.

The configuration according to the fifth configuration example is effective in enhancing the embeddability of the planar source electrode 29 and the film formability of the source pad 50. As a matter of course, the technical idea of the fourth configuration example may be adopted thereto, and the intermediate insulating film 24 may be removed (see FIG. 7C). In this case, the planar source electrode 29 opposes the surface layer drift region 14 across the gate insulating film 21 in the vertical direction Z in the insulating recess 26.

FIG. 7E is an enlarged cross-sectional view showing the first planar structure 20A according to the sixth configuration example. The feature according to the sixth configuration example is also applicable to any one or more of the first to fifth configuration examples. The first planar structure 20A according to the sixth configuration example has a form obtained by modifying the first planar structure 20A according to the fifth configuration example. In the fifth configuration example described above, the base electrode film 30 of the planar source electrode 29 is formed of a part of the base electrode film 46 of the source pad 50.

On the other hand, in the sixth configuration example, the base electrode film 30 is formed separately from the base electrode film 46. The base electrode film 30 may include at least one of a Ti film, a TiN film, and a W film as in the case of the first configuration example. The base electrode film 30 does not have a portion opposing the planar gate electrode 22 across the planar insulating film 27 in the vertical direction Z. The base electrode film 30 covers only the wall surface of the insulating recess 26 and the wall surface of the recess through hole 28 and exposes substantially an entire main surface of the planar insulating film 27.

In this example, the base electrode film 46 of the source pad 50 directly covers the planar insulating film 27, the base electrode film 30, and the electrode main body 31 and is physically and electrically connected to the planar source electrode 29 (the base electrode film 30 and the electrode main body 31). The base electrode film 46 of the source pad 50 is connected to the electrode surface of the planar source electrode 29 on the drift covering portion 21C side with respect to the main surface of the planar insulating film 27. The electrode main body film 47 of the source pad 50 covers the planar insulating film 27, the base electrode film 30, and the electrode main body 31 across the base electrode film 46.

The configuration according to the sixth configuration example is effective in enhancing the embeddability of the planar source electrode 29 and the film formability of the source pad 50. As a matter of course, the technical idea of the fourth configuration example may be adopted thereto, and the intermediate insulating film 24 may be removed (see FIG. 7C). In this case, the planar source electrode 29 opposes the surface layer drift region 14 across the gate insulating film 21 in the vertical direction Z in the insulating recess 26.

FIG. 7F is an enlarged cross-sectional view showing the first planar structure 20A according to the seventh configuration example. The feature according to the seventh configuration example is also applicable to any one or more of the first to sixth configuration examples. In the first configuration example, the planar source electrode 29 has a laminated structure including the base electrode film 30 and the electrode main body 31.

On the other hand, the planar source electrode 29 according to the seventh configuration example is constituted of a single-layer embedded electrode that is embedded as an integrated member in the insulating recess 26. In this embodiment, the planar source electrode 29 includes a That is, the planar source electrode 29 includes the same type of conductive polysilicon. conductive material as the planar gate electrode 22. The planar source electrode 29 may include either or both of p-type conductive polysilicon and n-type conductive polysilicon.

The planar source electrode 29 does not necessarily have the same conductivity type as the planar gate electrode 22. The conductivity type of the planar source electrode 29 may be the same as the conductivity type of the planar gate electrode 22, or may be different from the conductivity type of the planar gate electrode 22. For example, the planar gate electrode 22 may include n-type conductive polysilicon, while the planar source electrode 29 may include p-type conductive polysilicon. For example, the planar gate electrode 22 may include p-type conductive polysilicon, while the planar source electrode 29 may include n-type conductive polysilicon.

An electrode surface of the planar source electrode 29 is positioned on the gate insulating film 21 (the drift covering portion 21C) side with respect to a main surface of the planar insulating film 27 and is exposed from the insulating recess 26 (the recess through hole 28). The electrode surface of the planar source electrode 29 may be recessed toward the gate insulating film 21 (the drift covering portion 21C) side. The electrode surface of the planar source electrode 29 may be curved toward the gate insulating film 21 (the drift covering portion 21C). In this example, the electrode surface of the planar source electrode 29 is recessed in a curved shape toward the gate insulating film 21 (the drift covering portion 21C) side.

The base electrode film 46 of the source pad 50 covers the planar insulating film 27 and the electrode surface of the planar source electrode 29 and is physically and electrically connected to the planar source electrode 29. The base electrode film 46 is connected to the electrode surface of the planar source electrode 29 on the drift covering portion 21C side with respect to the main surface of the planar insulating film 27. The electrode main body film 47 of the source pad 50 covers the planar insulating film 27 and the planar source electrode 29 across the base electrode film 46.

The configuration according to the seventh configuration example is effective in enhancing the embeddability of the planar source electrode 29 and the film formability of the source pad 50. As a matter of course, the technical idea of the fourth configuration example may be adopted thereto, and the intermediate insulating film 24 may be removed (see FIG. 7C). In this case, the planar source electrode 29 opposes the surface layer drift region 14 across the gate insulating film 21 in the vertical direction Z in the insulating recess 26.

In the seventh configuration example, an example in which the planar source electrode 29 has a single layer structure constituted of conductive polysilicon is shown. However, the planar source electrode 29 may have a single layer structure constituted of a metal. For example, the planar source electrode 29 may have a single layer structure constituted of pure Ti, a Ti alloy (for example, TiN), pure W, a W alloy, pure Al, pure Cu, an Al alloy, or a Cu alloy. The planar source electrode 29 may have a single layer structure constituted of an AlCu alloy, an AlSi alloy, or an AlSiCu alloy.

FIG. 7G is an enlarged cross-sectional view showing the first planar structure 20A according to the eighth configuration example. FIG. 7G is an enlarged plan view showing the first planar structure 20A according to the eighth configuration example. The feature according to the eighth configuration example is also applicable to any one or more of the first to seventh configuration examples. In the first configuration example, the first electrode portion 22A and the second electrode portion 22B are defined by the through hole 23.

On the other hand, in the eighth configuration example, the through hole 23 that causes one of the first electrode portion 22A and the second electrode portion 22B (the second electrode portion 22B in FIG. 7G) to disappear is formed. That is, the planar gate electrode 22 is constituted of the other of the first electrode portion 22A and the second electrode portion 22B (the first electrode portion 22A in FIG. 7G).

In this example, the intermediate insulating film 24 covers the drift covering portion 21C and the second channel covering portion 21B and covers the second source region 11B, the second channel region 13B, and the surface layer drift region 14 across the gate insulating film 21 in the vertical direction. The separation insulating film 25 covers the wall surface of the first electrode portion 22A and defines the insulating recess 26 together with the intermediate insulating film 24 in the through hole 23. In this example, the insulating recess 26 is defined to be wider than the drift covering portion 21C and the second channel covering portion 21B.

The planar insulating film 27 covers the electrode surface of the first electrode portion 22A from above the first channel covering portion 21A through the wall surface of the first electrode portion 22A. The planar insulating film 27 is connected to the separation insulating film 25 above the first electrode portion 22A and defines the recess through hole 28 communicating with the insulating recess 26. In this example, the recess through hole 28 is defined to be wider than the drift covering portion 21C and the second channel covering portion 21B.

The plurality of source openings 44 are communicated with the insulating recess 26 and the recess through hole 28 on the second channel region 13B side. In this example, as the planar source electrode 29, a part of the source pad 50 is arranged in the insulating recess 26 (the recess through hole 28). Specifically, the source pad 50 enters into the insulating recess 26 from above the planar insulating films 27 through the recess through hole 28 and forms the planar source electrode 29.

The planar source electrode 29 opposes the planar gate electrode 22 across the separation insulating film 25 in the horizontal direction in the insulating recess 26 and is electrically insulated from the planar gate electrode 22 by the separation insulating film 25. The planar source electrode 29 opposes the second source region 11B, the second channel region 13B, and the surface layer drift region 14 across the intermediate insulating film 24 and the gate insulating film 21 in the vertical direction Z in the insulating recess 26.

The source pad 50 (the planar source electrode 29) enters into the source opening 44 from the insulating recess 26 and is electrically connected to the first source region 11A, the second source region 11B, and the contact region 12 in the source opening 44.

The planar source electrode 29 is fixed at the same potential as the second source region 11B and the second channel region 13B. Therefore, the planar source electrode 29 causes the function of the second channel region 13B to disappear and reduces a feedback capacitance Crss (=the gate-drain capacitance Cdg) between the surface layer drift region 14 and the planar gate electrode 22.

As a matter of course, the technical idea of the fourth configuration example may be adopted thereto, and the intermediate insulating film 24 may be removed (see FIG. 7C). In this case, the planar source electrode 29 opposes the second source region 11B, the second channel region 13B, and the surface layer drift region 14 across the gate insulating film 21 in the vertical direction Z in the insulating recess 26.

FIG. 7H is an enlarged plan view showing the first planar structure 20A according to the ninth configuration example. The feature according to the ninth configuration example is also applicable to any one or more of the first to eighth configuration examples. In the first configuration example described above, the through hole 23 is formed at an interval inward from the both end portions of the planar gate electrode 22.

On the other hand, in the ninth configuration example, the through hole 23 passes through any one or both of the both end portions of the planar gate electrode 22 in a plan view. In this example, the through hole 23 passes through both of the both end portions of the planar gate electrode 22 in a plan view and defines the planar gate electrode 22 (the first electrode portion 22A and the second electrode portion 22B) in a stripe shape. As a matter of course, the through hole 23 may pass through only one of the both end portions of the planar gate electrode 22 in a plan view and define the planar gate electrode 22 in a U shape.

FIG. 7I is an enlarged plan view showing the first planar structure 20A according to the tenth configuration example. The feature according to the tenth configuration example is also applicable to any one or more of the first to ninth configuration examples. In the first configuration example described above, one through hole 23 is formed in one planar gate electrode 22.

On the other hand, in the tenth configuration example, a plurality of through holes 23 are formed in one planar gate electrode 22. The plurality of through holes 23 are formed at intervals in the extension direction of the planar gate electrode 22 (the second direction Y) in a plan view. The plurality of through holes 23 define the planar gate electrode 22 in a lattice shape in a plan view.

A planar shape of each through hole 23 is arbitrary. Each through hole 23 may be formed in a quadrangular shape, a rectangular shape, a hexagonal shape, an octagonal shape, a circular shape, an elliptical shape, etc., in a plan view. A plurality of planar source electrodes 29 are arranged in the plurality of through holes 23. In this example, the plurality of planar source electrodes 29 are arranged in the plurality of through holes 23 at intervals in the extension direction of the planar gate electrode 22 (the second direction Y).

FIG. 7J is an enlarged cross-sectional view showing the first planar structure 20A according to the eleventh configuration example. The feature according to the eleventh configuration example is also applicable to any one or more of the first to tenth configuration examples. In the first configuration example described above, the first planar structure 20A has the gate insulating film 21, the planar gate electrode 22, the intermediate insulating film 24, the separation insulating film 25, the planar insulating film 27, and the planar source electrode 29.

On the other hand, the first planar structure 20A according to the eleventh configuration example has the gate insulating film 21, the intermediate insulating film 24, and the planar source electrode 29, and does not have the planar gate electrode 22, the separation insulating film 25, and the planar insulating film 27. The intermediate insulating film 24 covers substantially an entire region of the gate insulating film 21 and opposes the first source region 11A, the second source region 11B, the first channel region 13A, the second channel region 13B, and the surface layer drift region 14 across the gate insulating film 21 in the vertical direction Z.

A part of the source pad 50 described above is formed as the planar source electrode 29 and directly covers the intermediate insulating film 24. The planar source electrode 29 (the source pad 50) opposes the first source region 11A, the second source region 11B, the first channel region 13A, the second channel region 13B, and the surface layer drift region 14 across the intermediate insulating film 24 and the gate insulating film 21 in the vertical direction Z.

The planar source electrode 29 is fixed at the same potential as the first source region 11A, the second source region 11B, the first channel region 13A, and the second channel region 13B. The planar source electrode 29 causes the functions of the first channel region 13A and the second channel region 13B to disappear and reduces a feedback capacitance Crss (=the gate-drain capacitance Cdg).

The first planar structure 20A according to the eleventh configuration example cannot be used alone, since both the first channel region 13A and the second channel region 13B disappear. Therefore, the first planar structure 20A according to the eleventh configuration example is desirably used in combination with another planar structure. As a matter of course, the first planar structure 20A according to the eleventh configuration example may be partially incorporated in a partial region of another planar structure.

As a matter of course, the technical idea of the fourth configuration example may be adopted thereto, and the intermediate insulating film 24 may be removed (see FIG. 7C). In this case, the planar source electrode 29 opposes the first source region 11A, the second source region 11B, the first channel region 13A, the second channel region 13B, and the surface layer drift region 14 across the gate insulating film 21 in the vertical direction Z.

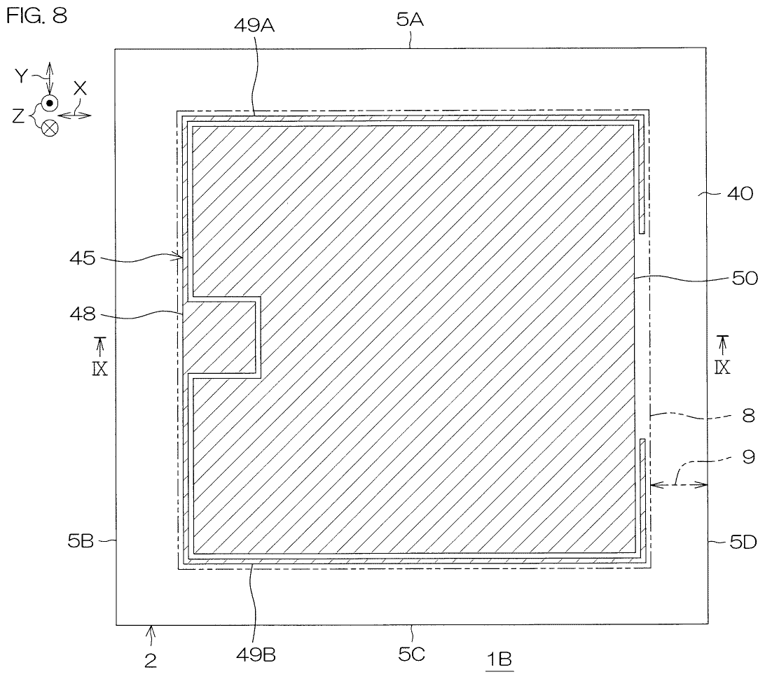

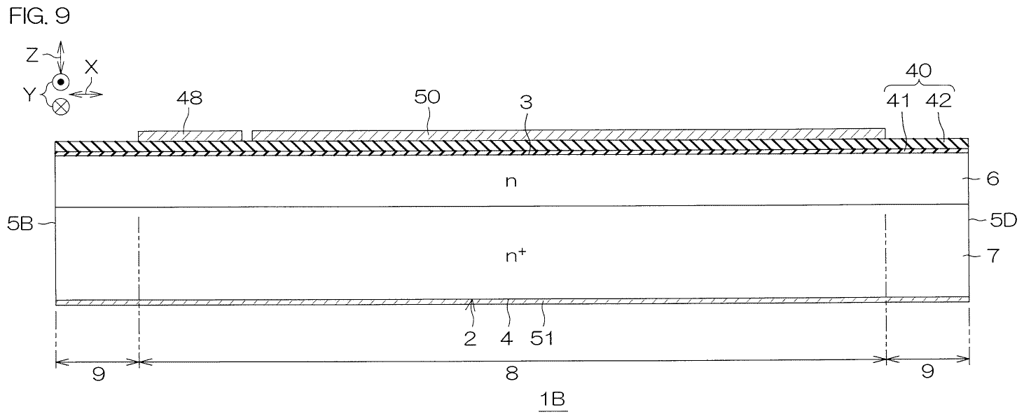

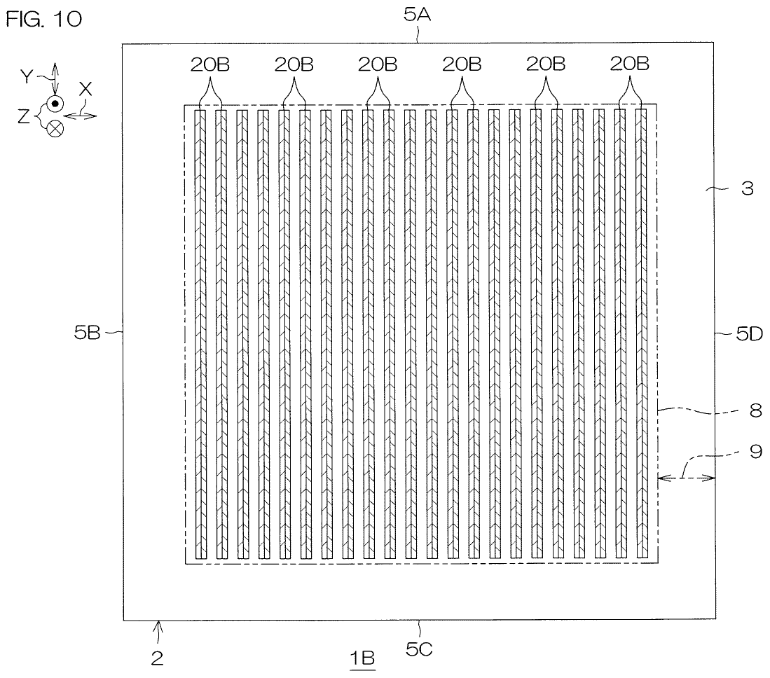

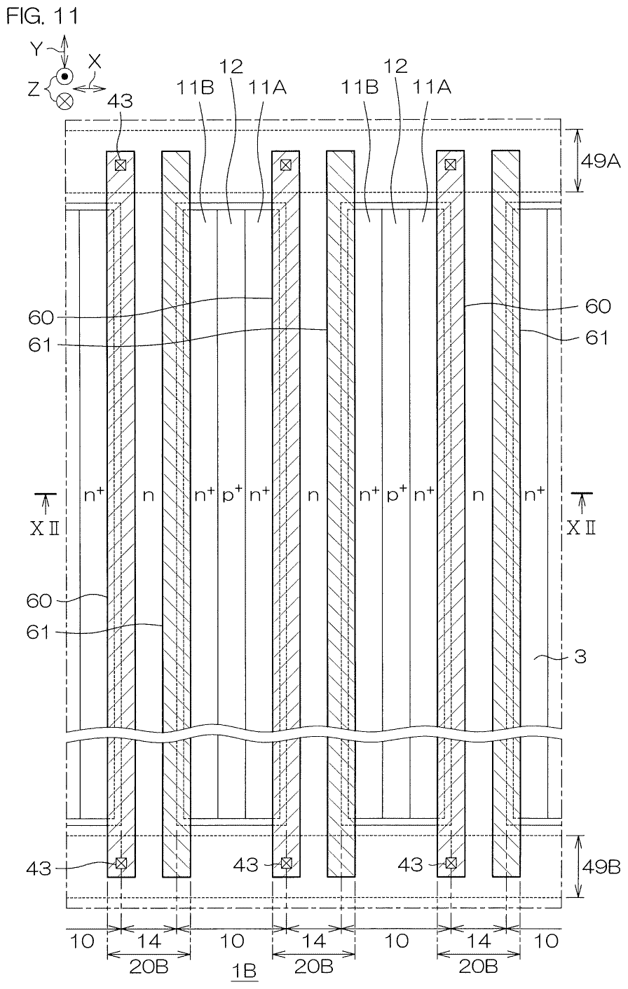

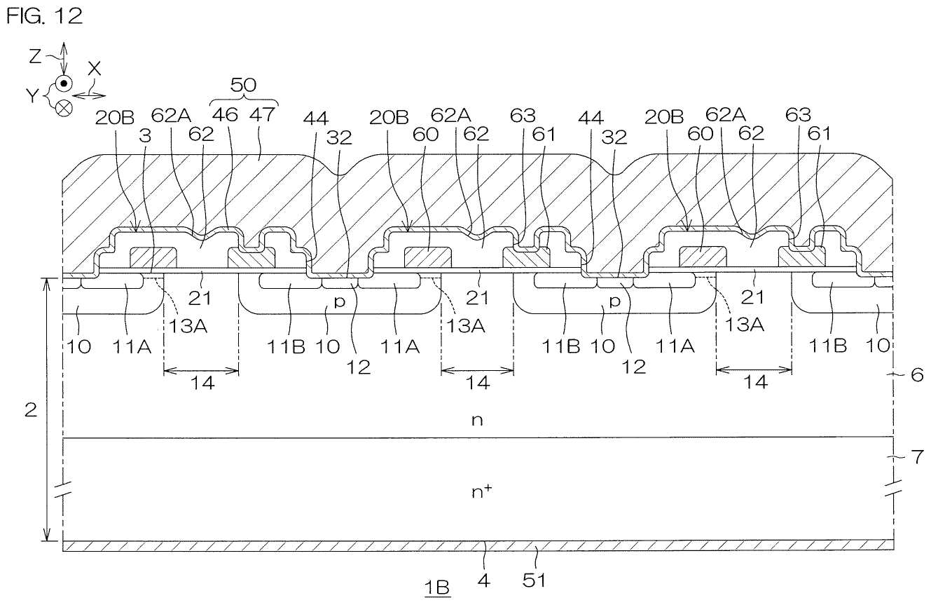

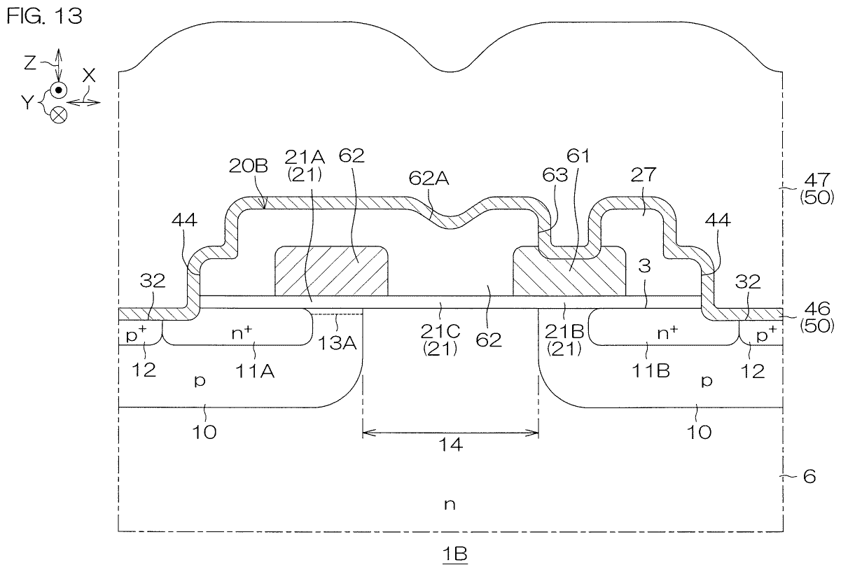

FIG. 8 is a plan view showing an SiC semiconductor device 1B according to a second embodiment. FIG. 9 is a cross-sectional view taken along line IX-IX shown in FIG. 8. FIG. 10 is a plan view showing a layout example of the chip 2 shown in FIG. 8. FIG. 11 is an enlarged plan view showing a layout example of the active region 8 together with a second planar structure 20B according to a first configuration example. FIG. 12 is a cross-sectional view taken along line XII-XII shown in FIG. 11. FIG. 13 is an enlarged cross-sectional view showing the second planar structure 20B.

Similarly to the SiC semiconductor device 1A, the SiC semiconductor device 1B includes the chip 2, the drift region 6, the drain region 7, the active region 8, the outer peripheral region 9, the plurality of body regions 10, the plurality of source regions 11A and 11B, the plurality of contact regions 12, the plurality of channel regions 13A and 13B, the plurality of surface layer drift regions 14, the plurality of contact recesses 32, the interlayer insulating film 40, the plurality of gate openings 43, the plurality of source openings 44, the gate pad 48, the gate wiring 49A, 49B, the source pad 50, and the drain pad 51.

Unlike the SiC semiconductor device 1A, the SiC semiconductor device 1B includes a plurality of the second planar structures 20B instead of the plurality of first planar structures 20A. Each of the plurality of second planar structures 20B includes the gate insulating film 21 that covers the first main surface 3. The gate insulating film 21 has the same form as in the case of the first embodiment.

Each of the plurality of second planar structures 20B includes a planar gate electrode 60 arranged on the gate insulating film 21. The planar gate electrode 60 is arranged on the first channel covering portion 21A at an interval from the second channel covering portion 21B and opposes the first channel region 13A across the first channel covering portion 21A in the vertical direction Z. The planar gate electrode 60 does not oppose the second channel region 13B in the vertical direction Z.

The planar gate electrode 60 controls inversion and non-inversion of the first channel region 13A in response to a gate potential from the outside. The planar gate electrode 60 may include either or both of p-type conductive polysilicon and n-type conductive polysilicon. The conductivity type of the planar gate electrode 60 is adjusted in accordance with the gate threshold voltage to be achieved.

The planar gate electrode 60 is formed in a band shape extending in the second direction Y on the first channel covering portion 21A. That is, the planar gate electrode 60 extends in the a-axis direction of the SiC monocrystal. Also, an extension direction of the planar gate electrode 60 is matched with the off direction of the SiC monocrystal.

The planar gate electrode 60 is led out from a portion on the first channel covering portion 21A onto the drift covering portion 21C and has a portion opposing the surface layer drift region 14 across the drift covering portion 21C. That is, the planar gate electrode 60 opposes the second channel region 13B through a part of the drift covering portion 21C in the horizontal direction.

The planar gate electrode 60 is preferably formed at an interval from the width direction intermediate portion of the drift covering portion 21C to the first channel covering portion 21A. That is, a hiding area of the planar gate electrode 60 with respect to the drift covering portion 21C is preferably less than the exposed area of the drift covering portion 21C. An opposing area of the planar gate electrode 60 with respect to the surface layer drift region 14 may be less than the opposing area of the planar gate electrode 60 with respect to the first channel region 13A.

The planar gate electrode 60 is capacitively coupled to the first source region 11A (the first channel region 13A) via the first channel covering portion 21A and is capacitively coupled to the surface layer drift region 14 via the drift covering portion 21C. The planar gate electrode 60 forms the gate-source capacitance Cgs together with the first source region 11A (the first channel region 13A) and forms the gate-drain capacitance Cdg together with the surface layer drift region 14. The gate-drain capacitance Cdg of the planar gate electrode 60 is preferably less than the gate-source capacitance Cgs of the planar gate electrode 60.

Each of the plurality of second planar structures 20B includes a planar source electrode 61 arranged on the gate insulating film 21. The planar source electrode 61 is arranged on the second channel covering portion 21B at an interval from the first channel covering portion 21A and opposes the planar gate electrode 60 across the drift covering portion 21C in the horizontal direction.

The planar source electrode 61 opposes the second channel region 13B across the second channel covering portion 21B in the vertical direction Z. The planar source electrode 61 does not oppose the first channel region 13A in the vertical direction Z. The planar source electrode 61 is fixed at the same potential as the second source region 11B (the second channel region 13B). The planar source electrode 61 causes the function of the second channel region 13B (see FIGS. 5 and 6) to disappear and reduces the feedback capacitance Crss (=the gate-drain capacitance Cdg) between the surface layer drift region 14 and the planar gate electrode 60.

The planar source electrode 61 may include either or both of p-type conductive polysilicon and n-type conductive polysilicon. The conductivity type of the planar source electrode 61 may be the same as the conductivity type of the planar gate electrode 60, or may be different from the conductivity type of the planar gate electrode 60.

For example, the planar gate electrode 60 may include n-type conductive polysilicon, while the planar source electrode 61 may include p-type conductive polysilicon. For example, the planar gate electrode 60 may include p-type conductive polysilicon, while the planar source electrode 61 may include n-type conductive polysilicon.

As a matter of course, when the planar gate electrode 60 includes an n-type region and a p-type region formed in the conductive polysilicon in the first layout, the planar source electrode 61 may include the n-type region and the p-type region formed in the conductive polysilicon in the second layout similar to the first layout. As a matter of course, the planar source electrode 61 may include the n-type region and the p-type region formed in the conductive polysilicon in the second layout different from the first layout.

The planar source electrode 61 is formed in a band shape extending in the second direction Y on the second channel covering portion 21B. That is, the planar source electrode 61 extends in the a-axis direction of the SiC monocrystal. Also, an extension direction of the planar source electrode 61 is matched with the off direction of the SiC monocrystal. The planar source electrode 61 extends substantially parallel to the planar gate electrode 60 on the same gate insulating film 21 in a plan view.

The planar source electrode 61 is led out from above the second channel covering portion 21B onto the drift covering portion 21C and has a portion opposing the surface layer drift region 14 across the drift covering portion 21C. That is, the planar source electrode 61 opposes the first channel region 13A across a part of the drift covering portion 21C in the horizontal direction in a plan view. An opposing area of the planar source electrode 61 with respect to the surface layer drift region 14 may be less than an opposing area of the planar source electrode 61 with respect to the second channel region 13B.

The planar source electrode 61 may be formed at an interval from the width direction intermediate portion of the drift covering portion 21C to the second channel covering portion 21B. That is, a hiding area of the planar source electrode 61 with respect to the drift covering portion 21C may be less than the exposed area of the drift covering portion 21C with respect to the planar source electrode 61.

In the first direction X, a width of the planar source electrode 61 may be substantially equal to a width of the planar gate electrode 60. As a matter of course, the width of the planar source electrode 61 may be less than the width of the planar gate electrode 60. Also, the width of the planar source electrode 61 may be greater than the width of the planar gate electrode 60.

The planar source electrode 61 may have one end portion positioned on the same straight line as one end portion of the planar gate electrode 60. As a matter of course, the one end portion of the planar source electrode 61 may be positioned closer to the active region 8 than the one end portion of the planar gate electrode 60. Also, the one end portion of the planar source electrode 61 may be positioned closer to the outer peripheral region 9 than the one end portion of the planar gate electrode 60.

The planar source electrode 61 may have another end portion positioned on the same straight line as another end portion of the planar gate electrode 60. As a matter of course, the other end portion of the planar source electrode 61 may be positioned closer to the active region 8 than the other end portion of the planar gate electrode 60. Also, the other end portion of the planar source electrode 61 may be positioned closer to the outer peripheral region 9 than the other end portion of the planar gate electrode 60.

The plurality of second planar structures 20B include a separation insulating film 62 interposed in a region between the planar gate electrode 60 and the planar source electrode 61. The separation insulating film 62 electrically insulates the planar gate electrode 60 and the planar source electrode 61 from each other in the horizontal direction on the same gate insulating film 21 (the drift covering portion 21C).

The separation insulating film 62 may include the same insulating material as the gate insulating film 21, or may include a different insulating material from the gate insulating film 21. The separation insulating film 62 may include at least one of a silicon oxide film, a silicon nitride film, and a silicon oxynitride film. In this embodiment, the separation insulating film 62 has a single layer structure constituted of a silicon oxide film.

The separation insulating film 62 is arranged on the drift covering portion 21C and has a portion opposing the surface layer drift region 14 across the drift covering portion 21C in the vertical direction Z. The separation insulating film 62 is connected to both a wall surface of the planar gate electrode 60 and a wall surface of the planar source electrode 61 and extends in the vertical direction Z along the wall surface of the planar gate electrode 60 and the wall surface of the planar source electrode 61.

The separation insulating film 62 is formed at an interval from the first channel region 13A and the second channel region 13B in the horizontal direction and opposes the surface layer drift region 14 in the vertical direction Z. The separation insulating film 62 does not oppose the first channel region 13A and the second channel region 13B in the vertical direction Z.

The separation insulating film 62 has a thickness greater than the thickness of the gate insulating film 21 in the vertical direction Z. The separation insulating film 62 has a lower end portion positioned below an electrode surface of the planar gate electrode 60 and an electrode surface of the planar source electrode 61 (on the drift covering portion 21C side), and an upper end portion protruding above the electrode surface of the planar gate electrode 60 and the electrode surface of the planar source electrode 61 (on the side opposite to the drift covering portion 21C).

A lower end portion of the separation insulating film 62 is connected to the drift covering portion 21C. An upper end portion of the separation insulating film 62 has a recess 62A recessed toward the drift covering portion 21C side. The recess 62A may be positioned above the electrode surface of the planar gate electrode 60 and the electrode surface of the planar source electrode 61. As a matter of course, the recess 62A may have a portion positioned below the electrode surface of the planar gate electrode 60 and the electrode surface of the planar source electrode 61.

The thickness of the separation insulating film 62 in the horizontal direction is less than a width of the drift covering portion 21C (the surface layer drift region 14). A thickness of the separation insulating film 62 in the horizontal direction is defined by a distance (an insulation distance) between the planar gate electrode 60 and the planar source electrode 61 adjacent to each other.

The thickness of the separation insulating film 62 in the horizontal direction may be greater than the thickness of the gate insulating film 21 in the vertical direction Z. The thickness of the separation insulating film 62 in the horizontal direction may be greater than a thickness of the planar gate electrode 60 in the vertical direction Z. As a matter of course, the thickness of the separation insulating film 62 in the horizontal direction may be less than the thickness of the planar gate electrode 60 in the vertical direction Z. Also, the thickness of the separation insulating film 62 in the horizontal direction may be less than the thickness of the gate insulating film 21 in the vertical direction Z.

Each of the plurality of second planar structures 20B includes the planar insulating film 27 that covers the planar gate electrode 60 and the planar source electrode 61. The planar insulating film 27 may include the same insulating material as the gate insulating film 21, or may include a different insulating material from the gate insulating film 21.

The planar insulating film 27 may include the same insulating material as the separation insulating film 62, or may include a different insulating material from the separation insulating film 62. The planar insulating film 27 may include at least one of a silicon oxide film, a silicon nitride film, and a silicon oxynitride film. In this embodiment, the planar insulating film 27 has a single layer structure constituted of a silicon oxide film.

The planar insulating film 27 covers the electrode surface of the planar gate electrode 60 from above the first channel covering portion 21A through the wall surface of the planar gate electrode 60 and covers the electrode surface of the planar source electrode 61 from above the second channel covering portion 21B through the wall surface of the planar source electrode 61.

In this embodiment, the planar insulating film 27 has a portion extending in a film shape in the horizontal direction along the first channel covering portion 21A, a portion extending in a film shape in the horizontal direction along the second channel covering portion 21B, a portion extending in a film shape in the horizontal direction along the electrode surface of the planar gate electrode 60, and a portion extending in a film shape in the horizontal direction along the electrode surface of the planar source electrode 61. A portion of the planar insulating film 27 which covers the planar gate electrode 60 and the planar source electrode 61 is positioned above a portion of the planar insulating film 27 which covers the first channel covering portion 21A and the second channel covering portion 21B.

The planar insulating film 27 is connected to the separation insulating film 62 in a region between the planar gate electrode 60 and the planar source electrode 61. In this embodiment, the planar insulating film 27 includes the same insulating material as the separation insulating film 62 and forms the separation insulating film 62 in the region between the planar gate electrode 60 and the planar source electrode 61. That is, a portion of the planar insulating film 27 which is positioned in the region between the planar gate electrode 60 and the planar source electrode 61 is formed as the separation insulating film 62.

The SiC semiconductor device 1B includes a plurality of planar source openings 63 that expose the plurality of planar source electrodes 61 in addition to the plurality of gate openings 43 and the plurality of source openings 44. The plurality of planar source openings 63 pass through the plurality of planar insulating films 27 and expose the plurality of planar source electrodes 61 in a one-to-one correspondence relationship.

The planar source opening 63 is formed on the inner side of the active region 8 with respect to the plurality of gate openings 43 and exposes the inner portion of the planar source electrode 61. In this embodiment, the planar source opening 63 is formed in a band shape extending in the second direction Y along the planar source electrode 61 in a plan view.

That is, the planar source opening 63 extends in the a-axis direction of the SiC monocrystal. Also, the extension direction of the planar source opening 63 is matched with the off direction of the SiC monocrystal. As a matter of course, the plurality of planar source openings 63 may be formed at intervals in the second direction Y such as to expose the corresponding single planar source electrode 61 from a plurality of places.

The second planar structure 20B may have a source recess portion 64 recessed toward the gate insulating film 21 in a portion exposed from the planar source opening 63 in the electrode surface of the planar source electrode 61. The source recess portion 64 is constituted of a thinned portion of the planar source electrode 61. That is, the source recess portion 64 has a bottom portion positioned closer to the gate insulating film 21 than a portion of the planar source electrode 61 hidden by the planar insulating film 27.

The bottom portion of the source recess portion 64 is positioned closer to the gate insulating film 21 than the electrode surface of the planar gate electrode 60. The bottom portion of the source recess portion 64 is preferably positioned closer to the electrode surface of the planar source electrode 61 than a thickness range intermediate portion of the planar source electrode 61. The source recess portion 64 is not necessarily formed, and a configuration not having the source recess portion 64 may be adopted.

In this embodiment, the first gate wiring 49A described above is led out from the gate pad 48 toward the first side surface 5A side and extends linearly along the peripheral edge of the active region 8 such as to intersect with (specifically, to be orthogonal to) parts (specifically, one end portions) of the plurality of second planar structures 20B. That is, the first gate wiring 49A covers the plurality of planar insulating films 27.

The first gate wiring 49A passes through the plurality of planar insulating films 27 through the plurality of gate openings 43 and is electrically connected to one end portions of the plurality of planar gate electrodes 60. The first gate wiring 49A may oppose one end portions of the plurality of planar source electrodes 61 across the plurality of planar insulating films 27 in the vertical direction Z and may be electrically insulated from the plurality of planar source electrodes 61 by the plurality of planar insulating films 27.

When one end portion of the planar source electrode 61 is positioned on the inner side of the active region 8 with respect to one end portion of the planar gate electrode 60, the first gate wiring 49A may be arranged at an interval from one end portions of the plurality of planar source electrodes 61 toward the outer peripheral region 9 side in a plan view.

In this embodiment, the second gate wiring 49B described above is led out from the gate pad 48 toward the third side surface 5C side and extends linearly along the peripheral edge of the active region 8 such as to intersect with (specifically, to be orthogonal to) parts (specifically, the other end portions) of the plurality of second planar structures 20B. That is, the second gate wiring 49B covers the plurality of planar insulating films 27.

The second gate wiring 49B passes through the plurality of planar insulating films 27 through the plurality of gate openings 43 and is electrically connected to the other end portions of the plurality of planar gate electrodes 60. The second gate wiring 49B may oppose the other end portions of the plurality of planar source electrodes 61 across the plurality of planar insulating films 27 in the vertical direction Z and may be electrically insulated from the plurality of planar source electrodes 61 by the plurality of planar insulating films 27.

When the other end portion of the planar source electrode 61 is positioned on the inner side of the active region 8 with respect to the other end portion of the planar gate electrode 60, the second gate wiring 49B may be arranged at an interval from the other end portions of the plurality of planar source electrodes 61 toward the outer peripheral region 9 side in a plan view.

The source pad 50 described above covers the plurality of second planar structures 20B (the plurality of planar insulating films 27) in the active region 8. The source pad 50 passes through the plurality of planar insulating films 27 and the plurality of gate insulating films 21 through the plurality of source openings 44 and is electrically connected to the plurality of first source regions 11A, the plurality of second source regions 11B, and the plurality of contact regions 12 as in the case of the first embodiment.

The source pad 50 passes through the plurality of planar insulating films 27 through the plurality of planar source openings 63 and is electrically connected to the plurality of planar source electrodes 61. A base electrode film 46 of the source pad 50 enters into the planar source opening 63 from above the planar insulating film 27 and covers the planar source electrode 61 in a film shape in the planar source opening 63.

The base electrode film 46 of the source pad 50 is electrically connected to the planar source electrode 61 in the planar source opening 63. The electrode main body film 47 of the source pad 50 enters into the planar source opening 63 from above the base electrode film 46 and is electrically connected to the planar source electrode 61 in the planar source opening 63 across the base electrode film 46.

Hereinafter, second to sixth configuration examples of the second planar structure 20B will be described. The second planar structure 20B may have one or more of the features of the second to sixth configuration examples instead of or in addition to the feature of the first configuration example. That is, the second planar structure 20B may have at least one feature of the first to sixth configuration examples.

The second planar structure 20B may have a feature in which a plurality of features of the first to sixth configuration examples are combined. The second planar structure 20B may partially have one or more of the features of the first to sixth configuration examples in a different region.

The SiC semiconductor device 1B may simultaneously include at least two second planar structures 20B of the second planar structures 20B according to the first to sixth configuration examples in the active region 8.

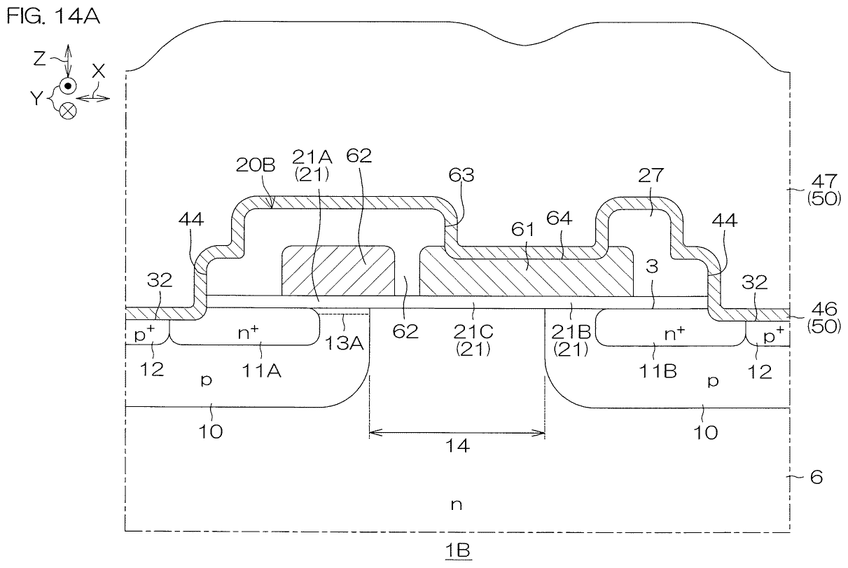

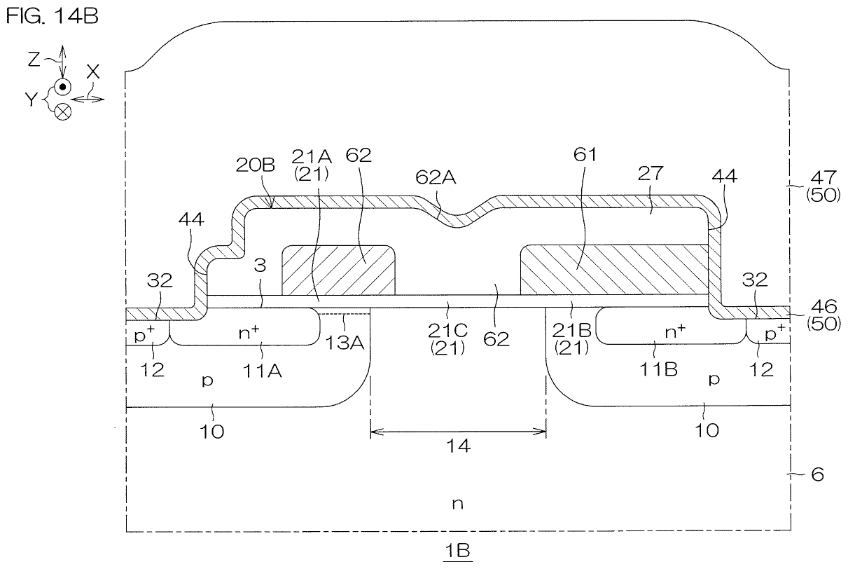

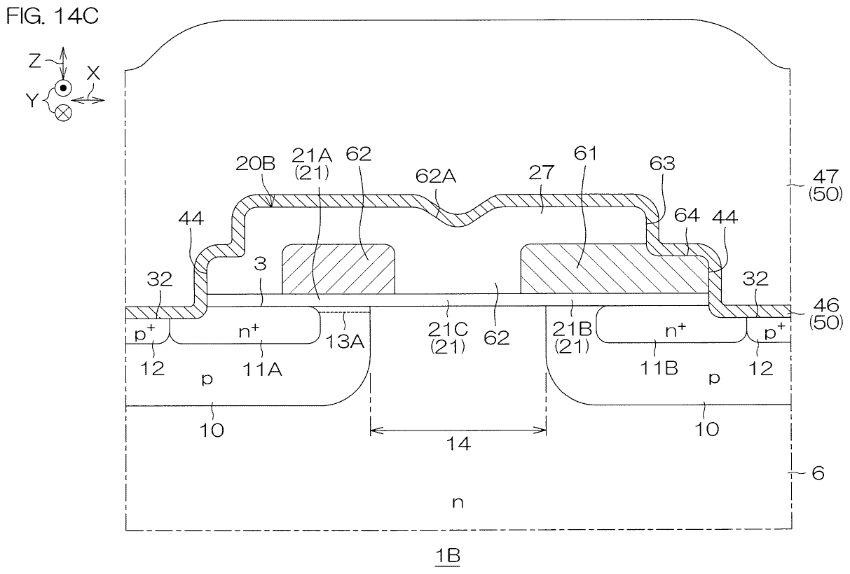

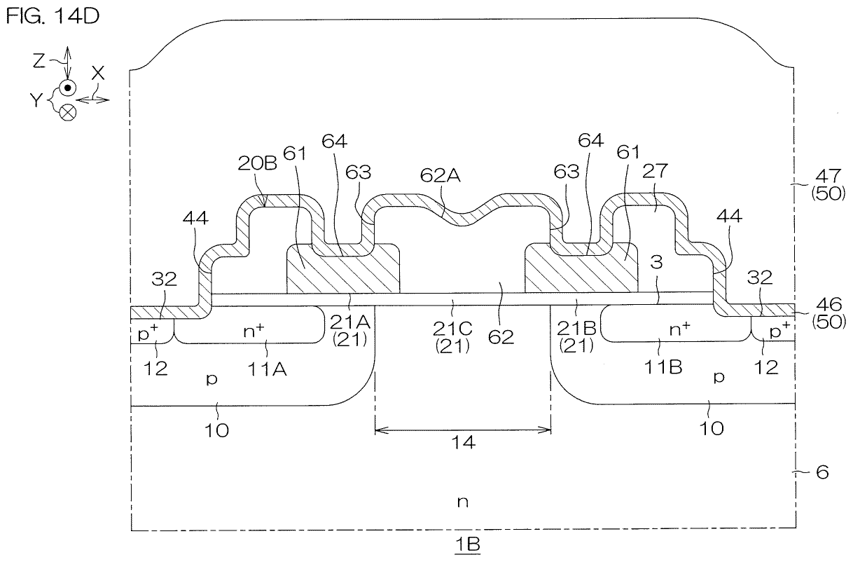

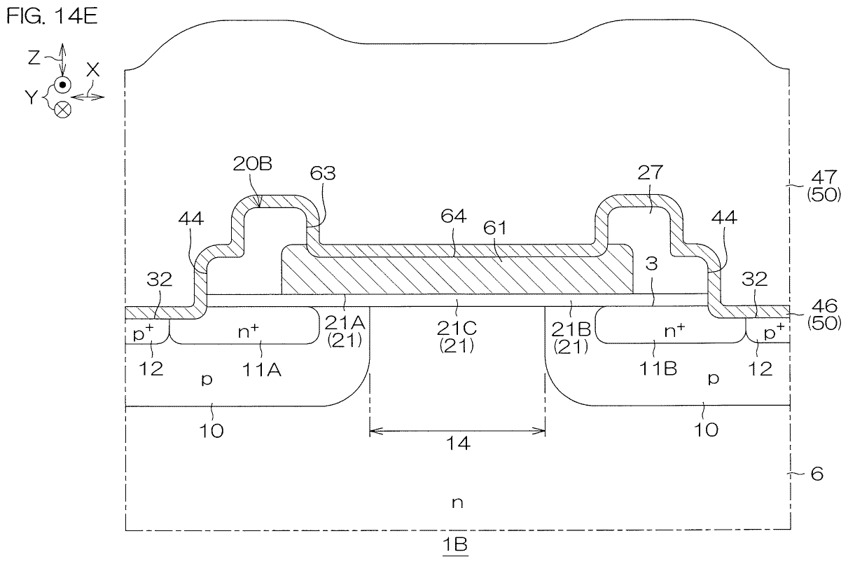

FIG. 14A is an enlarged cross-sectional view showing the second planar structure 20B according to the second configuration example. With reference to FIG. 14A, the planar source electrode 61 may be formed to be wider than the planar gate electrode 60. For example, the planar source electrode 61 may be formed to be wider than the surface layer drift region 14.

For example, the opposing area of the planar source electrode 61 with respect to the surface layer drift region 14 may be greater than the opposing area of the planar source electrode 61 with respect to the second channel region 13B. For example, the opposing area of the planar source electrode 61 with respect to the surface layer drift region 14 may be greater than the opposing area of the planar gate electrode 60 with respect to the surface layer drift region 14.

The planar source electrode 29 is capacitively coupled to the surface layer drift region 14 via the drift covering portion 21C and forms a drain-source capacitance Cds together with the surface layer drift region 14. In this case, the drain-source capacitance Cds is preferably greater than a feedback capacitance Crss (=the gate-drain capacitance Cdg) between the surface layer drift region 14 and the planar gate electrode 60.

The thickness of the separation insulating film 62 in the horizontal direction is less than a width of the drift covering portion 21C (the surface layer drift region 14). The thickness of the separation insulating film 62 in the horizontal direction may be greater than the thickness of the gate insulating film 21 in the vertical direction Z. The thickness of the separation insulating film 62 in the horizontal direction may be greater than the thickness of the planar gate electrode 60 (the planar source electrode 61) in the vertical direction Z. As a matter of course, the thickness of the separation insulating film 62 in the horizontal direction may be less than the thickness of the planar gate electrode 60 (the planar source electrode 61) in the vertical direction Z. Also, the thickness of the separation insulating film 62 in the horizontal direction may be less than the thickness of the gate insulating film 21 in the vertical direction Z.

When such a planar source electrode 61 is adopted, the limitation of the layout of the planar source opening 63 is relaxed. For example, the planar source opening 63 may have at least one of a portion opposing the second source region 11B, a portion opposing the second channel region 13B, and a portion opposing the surface layer drift region 14. For example, the planar source opening 63 may have both the portion opposing the second channel region 13B and the portion opposing the surface layer drift region 14.

For example, the planar source opening 63 may be formed to be wider than the second channel region 13B. For example, the planar source opening 63 may be formed to be wider than the planar gate electrode 60. For example, the planar source opening 63 may be formed to be wider than the surface layer drift region 14.

As a matter of course, the planar source opening 63 may be formed to be narrower than the surface layer drift region 14. The planar source opening 63 may be formed to be narrower than the planar gate electrode 60. The planar source opening 63 may be formed to be narrower than the second channel region 13B.

FIG. 14B is an enlarged cross-sectional view showing the second planar structure 20B according to the third configuration example. The feature according to the third configuration example is also applicable to the second configuration example. With reference to FIG. 14B, the planar source electrode 61 may be exposed from the end portion of the second channel covering portion 21B (the gate insulating film 21).

The opposing area of the planar source electrode 61 with respect to the second source region 11B may be greater than the opposing area of the planar source electrode 61 with respect to the second channel region 13B. The opposing area of the planar source electrode 61 with respect to the second source region 11B may be greater than the opposing area of the planar gate electrode 60 with respect to the first source region 11A.

In this embodiment, the planar insulating film 27 covers an entire electrode surface of the planar source electrode 61 and does not have the planar source opening 63. The source opening 44 passes through the planar insulating film 27, the planar source electrode 61, and the gate insulating film 21 on the second channel covering portion 21B side and exposes the first source region 11A, the second source region 11B, the contact region 12, and the planar source electrode 61. The source pad 50 is electrically connected to the first source region 11A, the second source region 11B, the contact region 12, and the planar source electrode 61 in the source opening 44.

FIG. 14C is an enlarged cross-sectional view showing the second planar structure 20B according to the fourth configuration example. The feature according to the fourth configuration example has a form obtained by modifying the third configuration example. In the fourth configuration example, a planar source opening 63 that exposes the electrode surface of the planar source electrode 61 is formed. In this embodiment, the planar source opening 63 exposes an end portion of the electrode surface of the planar source electrode 61 on the side opposite to the planar gate electrode 60.

In this embodiment, the source opening 44 is communicated with the planar source opening 63. As a matter of course, as in the first configuration example, the planar source opening 63 may expose the inner portion of the electrode surface of the planar source electrode 61, and the source opening 44 may be formed at an interval from the planar source opening 63.

FIG. 14D is an enlarged cross-sectional view showing the second planar structure 20B according to the fifth configuration example. With reference to FIG. 14D, the second planar structure 20B does not necessarily include both the planar gate electrode 60 and the planar source electrode 61 at the same time. In the second planar structure 20B, the planar gate electrode 60 may be replaced with the planar source electrode 61.

That is, the second planar structure 20B may include one planar source electrode 61 opposing the first channel region 13A across the first channel covering portion 21A in the vertical direction Z and the other planar source electrode 61 opposing the second channel region 13B across the second channel covering portion 21B in the vertical direction Z.

The one planar source electrode 61 has the same configuration as the other planar source electrode 61 except that the one planar source electrode 61 is arranged on the first channel covering portion 21A side. The description of the configuration of the planar source electrode 61 side on the first channel region 13A side is omitted assuming that the description of the configuration of the planar source electrode 61 side on the second channel region 13B side is applied thereto. The source pad 50 described above is electrically connected to both the one planar source electrode 61 and the other planar source electrode 61 via the plurality of planar source openings 63.

In this example, the one planar source electrode 61 opposes the first source region 11A and the first channel region 13A across the gate insulating film 21 in the vertical direction Z and is fixed at the same potential as the first source region 11A and the first channel region 13A. The one planar source electrode 61 causes the function of the first channel region 13A to disappear and reduces a feedback capacitance Crss (=the gate-drain capacitance Cdg).

The other planar source electrode 61 opposes the second source region 11B and the second channel region 13B across the gate insulating film 21 in the vertical direction Z and is fixed at the same potential as the second source region 11B and the second channel region 13B. The other planar source electrode 61 causes the function of the second channel region 13B to disappear and reduces a feedback capacitance Crss (=the gate-drain capacitance Cdg).

The second planar structure 20B according to the fifth configuration example cannot be used alone, since both the first channel region 13A and the second channel region 13B disappear. Therefore, the second planar structure 20B according to the fifth configuration example is desirably used in combination with another planar structure. As a matter of course, the second planar structure 20B according to the fifth configuration example may be partially incorporated in a partial region of another planar structure.

FIG. 14E is an enlarged cross-sectional view showing the second planar structure 20B according to the sixth configuration example. The second planar structure 20B according to the sixth configuration example has a form obtained by modifying the second planar structure 20B according to the fifth configuration example. Specifically, in the second planar structure 20B, the planar source electrode 61 on the first channel covering portion 21A side and the planar source electrode 61 on the second channel covering portion 21B side are integrated with each other.

That is, the second planar structure 20B according to the sixth configuration example includes a single planar source electrode 61. The single planar source electrode 61 is formed to be wider than the surface layer drift region 14 and opposes the first source region 11A, the second source region 11B, the first channel region 13A, the second channel region 13B, and the surface layer drift region 14 across the gate insulating film 21 in the vertical direction Z.

The single planar source electrode 61 is fixed at the same potential as the first source region 11A, the second source region 11B, the first channel region 13A, and the second channel region 13B. The single planar source electrode 61 causes the functions of the first channel region 13A and the second channel region 13B to disappear and reduces a feedback capacitance Crss (=the gate-drain capacitance Cdg).

The planar insulating film 27 has one or more planar source openings 63 that selectively expose the electrode surface of the planar source electrode 61. In FIG. 14E, an example in which the single planar source opening 63 is formed is shown. The planar source opening 63 may oppose the surface layer drift region 14 across the planar source electrode 61 in the vertical direction Z.

The planar source opening 63 may be formed to be wider than the first channel region 13A. The planar source opening 63 may be formed to be wider than the second channel region 13B. The planar source opening 63 may be formed to have a width greater than a total width of the first channel region 13A and the second channel region 13B. The planar source opening 63 may be formed to be wider than the surface layer drift region 14. The planar source opening 63 may be formed to have a width greater than a total width of the first channel region 13A, the second channel region 13B, and the surface layer drift region 14.

As a matter of course, the planar source opening 63 may be formed to have a width smaller than the total width of the first channel region 13A, the second channel region 13B, and the surface layer drift region 14. The planar source opening 63 may be formed to be narrower than the surface layer drift region 14. The planar source opening 63 may be formed to have a width smaller than the total width of the first channel region 13A and the second channel region 13B. The planar source opening 63 may be formed to be narrower than the first channel region 13A. The planar source opening 63 may be formed to be narrower than the second channel region 13B.

The second planar structure 20B according to the sixth configuration example cannot be used alone, since both the first channel region 13A and the second channel region 13B disappear. Therefore, the second planar structure 20B according to the sixth configuration example is desirably used in combination with another planar structure. As a matter of course, the second planar structure 20B according to the sixth configuration example may be partially incorporated in a partial region of another planar structure.

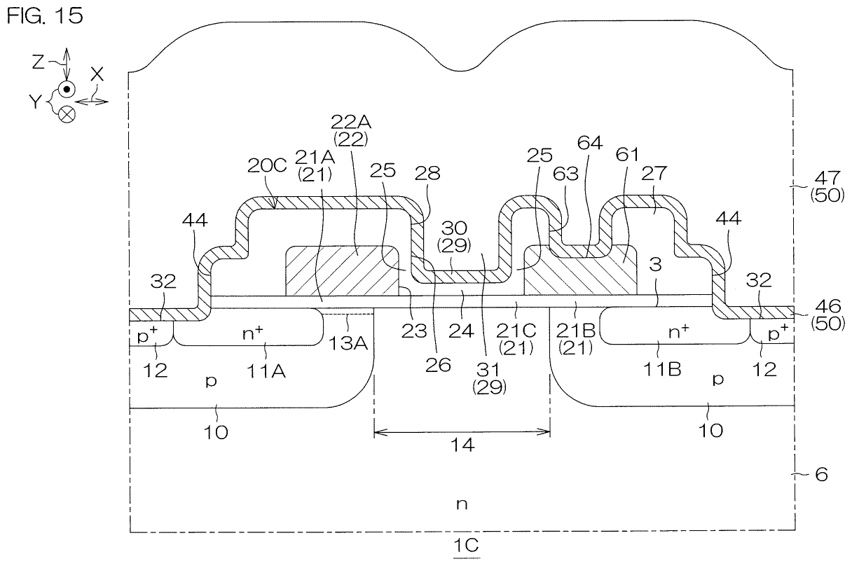

FIG. 15 is an enlarged cross-sectional view showing a main part of an SiC semiconductor device 1C according to a third embodiment. The SiC semiconductor device 1C includes a third planar structure 20C. The third planar structure 20C has a structure in which the configuration (the planar source electrode 29) of the first planar structure 20A (see FIG. 6) according to the first embodiment is combined with the second planar structure 20B (see FIG. 13) according to the second embodiment.

FIG. 15 illustrates an example in which the first planar structure 20A (see FIG. 6) according to the first configuration example is applied to the second planar structure 20B (see FIG. 13) according to the first configuration example. However, at least one feature of the first planar structure 20A (see FIGS. 7A to 7J) according to the second to eleventh configuration examples may be incorporated into a part or all of at least one feature of the second planar structure 20B (see FIGS. 14A to 14E) according to the second to sixth configuration examples.

The third planar structure 20C includes the through hole 23 that separates the planar gate electrode 60 and the planar source electrode 61 from each other. The through hole 23 is formed at an interval inward from the first channel covering portion 21A and the second channel covering portion 21B in a cross-sectional view and in a plan view. That is, the through hole 23 exposes only the drift covering portion 21C.

In this embodiment, the through hole 23 is formed in a band shape extending in the second direction Y in a plan view and physically and electrically separates the planar gate electrode 60 and the planar source electrode 61 from each other. That is, the through hole 23 extends in the a-axis direction of the SiC monocrystal. Also, the extension direction of the through hole 23 is matched with the off direction of the SiC monocrystal.

The third planar structure 20C includes the intermediate insulating film 24 that covers the drift covering portion 21C in a film shape in the through hole 23. The intermediate insulating film 24 is in contact with the wall surface of the planar gate electrode 60 and the wall surface of the planar source electrode 61 in a cross-sectional view.

The intermediate insulating film 24 is formed at an interval from the first channel region 13A and the second channel region 13B in the horizontal direction. The intermediate insulating film 24 opposes the surface layer drift region 14 across the drift covering portion 21C and does not oppose the first channel region 13A and the second channel region 13B.

The intermediate insulating film 24 has a thickness less than the thickness of the planar gate electrode 60 and the thickness of the planar source electrode 61 and is formed at an interval from the electrode surface of the planar gate electrode 60 and the electrode surface of the planar source electrode 61 toward the gate insulating film 21 side. The intermediate insulating film 24 may have a thickness greater than a thickness of the gate insulating film 21. The intermediate insulating film 24 may have a thickness less than the thickness of the gate insulating film 21. As a matter of course, the technical idea of the fourth configuration example may be adopted thereto, and the intermediate insulating film 24 may be removed (see FIG. 7C).

The third planar structure 20C includes the separation insulating film 25 that covers the wall surface of the planar gate electrode 60 and the wall surface of the planar source electrode 61 in the through hole 23. The separation insulating film 25 is arranged on the drift covering portion 21C and has a portion opposing the surface layer drift region 14 across the drift covering portion 21C in the vertical direction Z.

The separation insulating film 25 extends in the vertical direction Z along the wall surface of the planar gate electrode 60 and the wall surface of the planar source electrode 61 and covers the wall surface of the planar gate electrode 60 and the wall surface of the planar source electrode 61 in a film shape. The separation insulating film 25 is connected to the gate insulating film 21 (the drift covering portion 21C) and the intermediate insulating film 24 on the lower end side of the planar gate electrode 60 and the lower end side of the planar source electrode 61.

The separation insulating film 25 is formed at an interval from both the first channel region 13A and the second channel region 13B in the horizontal direction and does not oppose both the first channel region 13A and the second channel region 13B in the vertical direction Z. The separation insulating film 25 defines the insulating recess 26 together with the intermediate insulating film 24 in the through hole 23. The insulating recess 26 is formed in a band shape extending along the through hole 23 in a plan view. The insulating recess 26 is formed to be narrower than the surface layer drift region 14 in a cross-sectional view.

The third planar structure 20C includes the planar insulating film 27 that covers the planar gate electrode 60 and the planar source electrode 61. The planar insulating film 27 covers the electrode surface of the planar gate electrode 60 from above the first channel covering portion 21A through the wall surface of the planar gate electrode 60 and covers the electrode surface of the planar source electrode 61 from above the second channel covering portion 21B through the wall surface of the planar source electrode 61.

In this embodiment, the planar insulating film 27 has a portion extending in a film shape in the horizontal direction along the first channel covering portion 21A, a portion extending in a film shape in the horizontal direction along the second channel covering portion 21B, a portion extending in a film shape in the horizontal direction along the planar gate electrode 60, and a portion extending in a film shape in the horizontal direction along the planar source electrode 61. A portion of the planar insulating film 27 which covers the planar gate electrode 60 and the planar source electrode 61 is positioned above a portion of the planar insulating film 27 which covers the first channel covering portion 21A and the second channel covering portion 21B.

The planar insulating film 27 is connected to the separation insulating film 25 in the inner portion of the planar gate electrode 60 and the inner portion of the planar source electrode 61 and defines the recess through hole 28 communicating with the insulating recess 26. The recess through hole 28 is formed in a band shape extending along the insulating recess 26 in a plan view. In this embodiment, the recess through hole 28 is formed to be narrower than the surface layer drift region 14 in a cross-sectional view.

The third planar structure 20C includes the planar source electrode 29 arranged over the gate insulating film 21. The planar source electrode 29 is arranged over the drift covering portion 21C at an interval from both the planar gate electrode 60 and the planar source electrode 61 such as to oppose both the planar gate electrode 60 and the planar source electrode 61 in the horizontal direction and opposes the surface layer drift region 14 across the drift covering portion 21C in the vertical direction Z.

Specifically, the planar source electrode 29 is arranged in the insulating recess 26. The planar source electrode 29 is formed in a band shape extending in the second direction Y (the a-axis direction) along the insulating recess 26 in a plan view. That is, the planar source electrode 29 extends substantially parallel to the planar gate electrode 60 and the planar source electrode 61.

The planar source electrode 29 opposes both the planar gate electrode 60 and the planar source electrode 61 across the separation insulating film 25 in the horizontal direction in the insulating recess 26 and is electrically insulated from the planar gate electrode 22 by the separation insulating film 25.

In this embodiment, the planar source electrode 29 protrudes from the insulating recess 26 toward the recess through hole 28 side and has a portion positioned in the recess through hole 28. That is, the planar source electrode 29 has a portion positioned below the electrode surface (an upper end portion) of the planar gate electrode 60 and the electrode surface (an upper end portion) of the planar source electrode 61 (on the gate insulating film 21 side) and a portion positioned above the electrode surface (the upper end portion) of the planar gate electrode 60 and the electrode surface (an upper end portion) of the planar source electrode 61 (on the side opposite to the gate insulating film 21).

The planar source electrode 29 has a portion in contact with the intermediate insulating film 24 and the separation insulating film 25 in the insulating recess 26 and has a portion in contact with the planar insulating film 27 in the recess through hole 28. That is, the planar source electrode 29 opposes the surface layer drift region 14 across the intermediate insulating film 24 and the gate insulating film 21 in the vertical direction Z in the insulating recess 26.

In this embodiment, the planar source electrode 29 includes a different conductive material from the planar gate electrode 60 and the planar source electrode 61. Specifically, the planar source electrode 29 includes a metal. More specifically, the planar source electrode 29 includes a metal base electrode film 30 and a metal electrode main body 31. As a matter of course, the planar source electrode 29 may include the same type of conductive material as the planar gate electrode 60 and the planar source electrode 61 (see FIGS. 7D to 7F). Besides the above, the description of the first planar structure 20A is applied to the description of the planar source electrode 29.

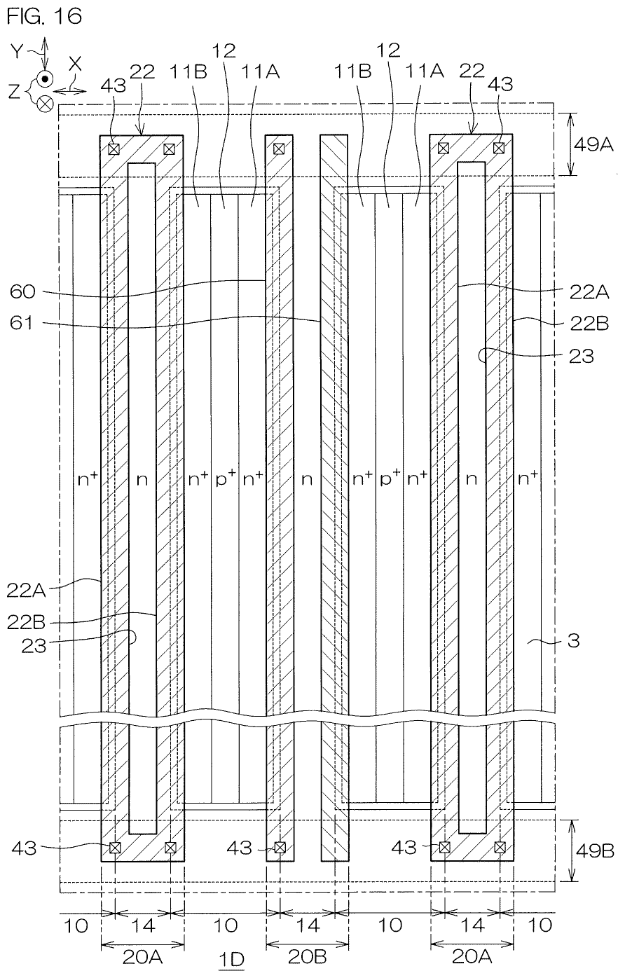

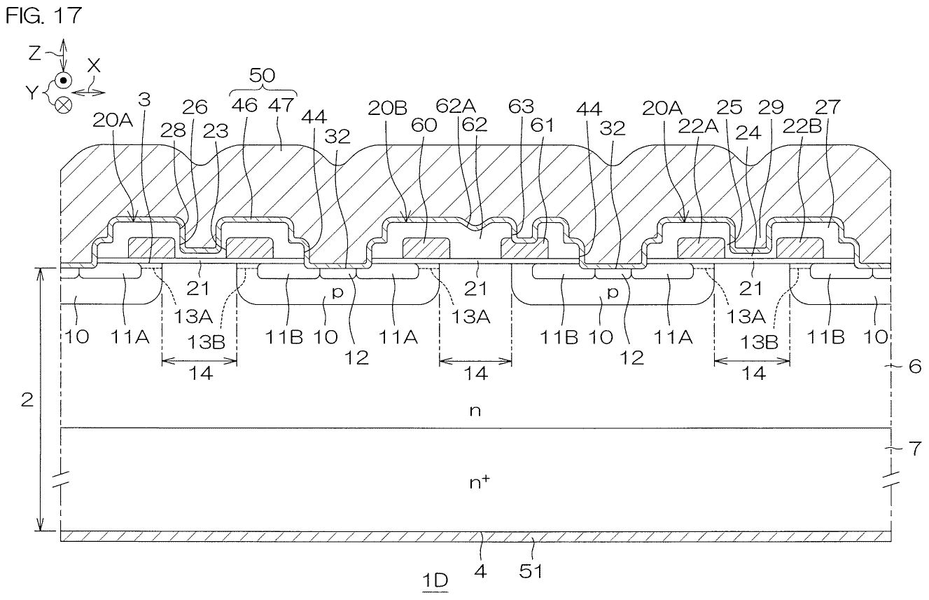

FIG. 16 is an enlarged plan view showing a layout example of an active region 8 of an SiC semiconductor device 1D according to a fourth embodiment. FIG. 17 is a cross-sectional view taken along line XVII-XVII shown in FIG. 16. The SiC semiconductor device 1D simultaneously includes both one or more first planar structures 20A and one or more second planar structures 20B.

FIGS. 16 and 17 illustrate an example in which the SiC semiconductor device 1D includes the first planar structure 20A (see FIG. 6) according to the first configuration example and the second planar structure 20B (see FIG. 13) according to the first configuration example. However, the SiC semiconductor device 1D may include at least one of the first planar structures 20A (see FIGS. 7A to 7J) according to the second to eleventh configuration examples instead of or in addition to the first planar structure 20A (see FIG. 6) according to the first configuration example.

The SiC semiconductor device 1D may include at least one of the second planar structures 20B (see FIGS. 14A to 14E) according to the second to sixth configuration examples instead of or in addition to the second planar structure 20B (see FIG. 13) according to the first configuration example.

The number of the first planar structures 20A and the number of the second planar structures 20B are appropriately adjusted in accordance with the feedback capacitance Crss to be achieved. For example, the SiC semiconductor device 1D may have a layout portion in which a plurality of first planar structures 20A and at least one second planar structure 20B are alternately arranged in the first direction X.

For example, the SiC semiconductor device 1D may have a layout portion in which at least one first planar structure 20A and a plurality of second planar structures 20B are alternately arranged in the first direction X. As a matter of course, the SiC semiconductor device 1D may include one or more third planar structures 20C instead of any one or both of the one or more first planar structures 20A and the one or more second planar structures 20B.

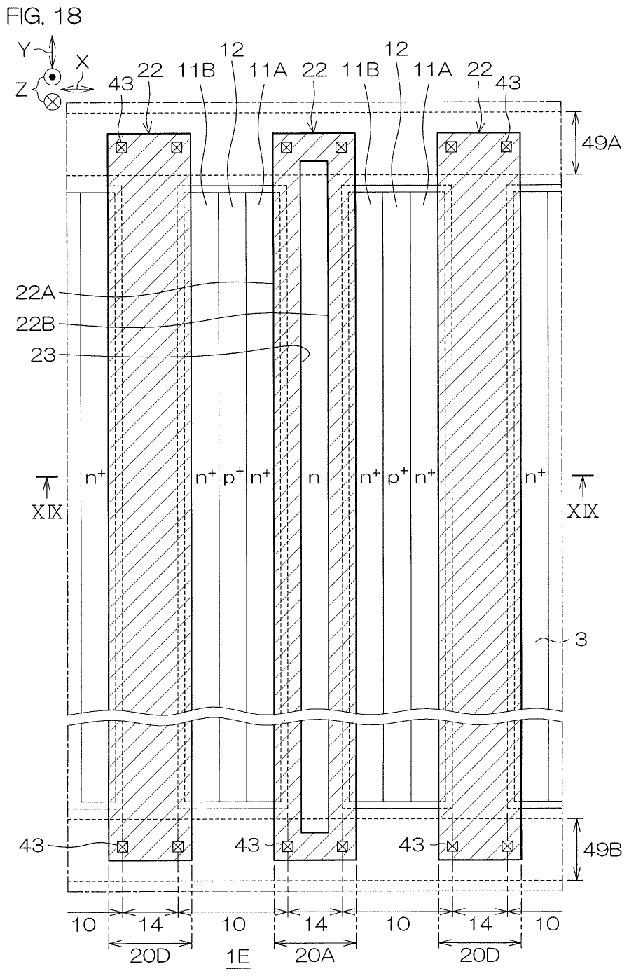

FIG. 18 is an enlarged plan view showing a layout example of an active region 8 of an SiC semiconductor device 1E according to a fifth embodiment. The SiC semiconductor device 1E simultaneously includes both one or more first planar structures 20A and one or more fourth planar structures 20D.

The fourth planar structure 20D is a normal planar structure not having the through hole 23, the intermediate insulating film 24, the separation insulating film 25, and the planar source electrode 29. In the fourth planar structure 20D, the planar gate electrode 22 opposes the first source region 11A, the second source region 11B, the first channel region 13A, the second channel region 13B, and the surface layer drift region 14 across the gate insulating film 21 in the vertical direction Z.

That is, the planar gate electrode 22 according to the fourth planar structure 20D controls inversion and non-inversion of both the first channel region 13A and the second channel region 13B. The planar gate electrode 22 according to the fourth planar structure 20D is capacitively coupled to the plurality of source regions 11A and 11B (the plurality of channel regions 13A and 13B) via the plurality of channel covering portions 21A and 21B and is capacitively coupled to the surface layer drift region 14 via the drift covering portion 21C.

The planar gate electrode 22 according to the fourth planar structure 20D forms a gate-source capacitance Cgs together with the plurality of source regions 11A and 11B (the plurality of channel regions 13A and 13B) and forms a gate-drain capacitance Cdg together with the surface layer drift region 14. The gate-source capacitance Cgs of the fourth planar structure 20D is substantially equal to the gate-source capacitance Cgs of the first planar structure 20A. The gate-drain capacitance Cdg of the fourth planar structure 20D is greater than the gate-drain capacitance Cdg of the first planar structure 20A.

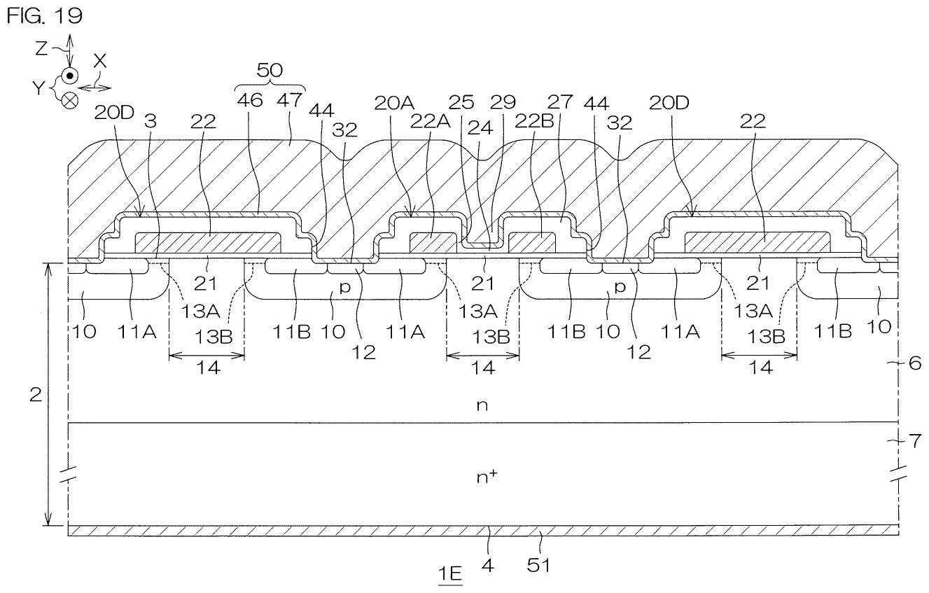

FIGS. 18 and 19 illustrate an example in which the SiC semiconductor device 1E includes the first planar structure 20A (see FIG. 6) according to the first configuration example. However, the SiC semiconductor device 1E may include at least one of the first planar structures 20A (see FIGS. 7A to 7J) according to the second to eleventh configuration examples instead of or in addition to the first planar structure 20A (see FIG. 6) according to the first configuration example.

The number of the first planar structures 20A and the number of the fourth planar structures 20D are appropriately adjusted in accordance with the feedback capacitance Crss to be achieved. For example, the SiC semiconductor device 1E may have a layout portion in which a plurality of first planar structures 20A and at least one fourth planar structure 20D are alternately arranged in the first direction X.

For example, the SiC semiconductor device 1E may have a layout portion in which at least one first planar structure 20A and a plurality of fourth planar structures 20D are alternately arranged in the first direction X. As a matter of course, the SiC semiconductor device 1E may include the third planar structure 20C instead of or in addition to the first planar structure 20A.

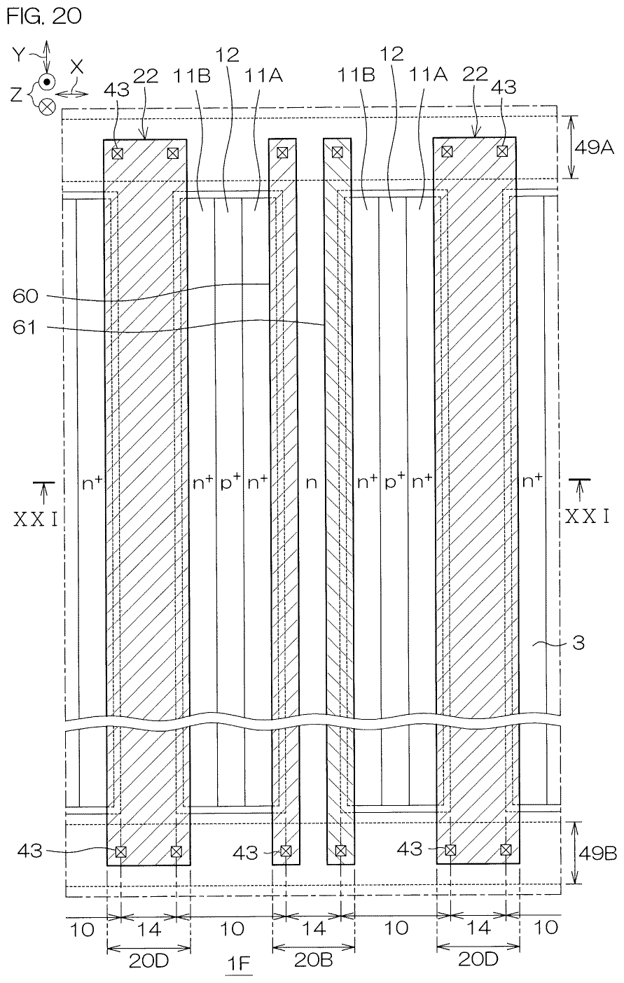

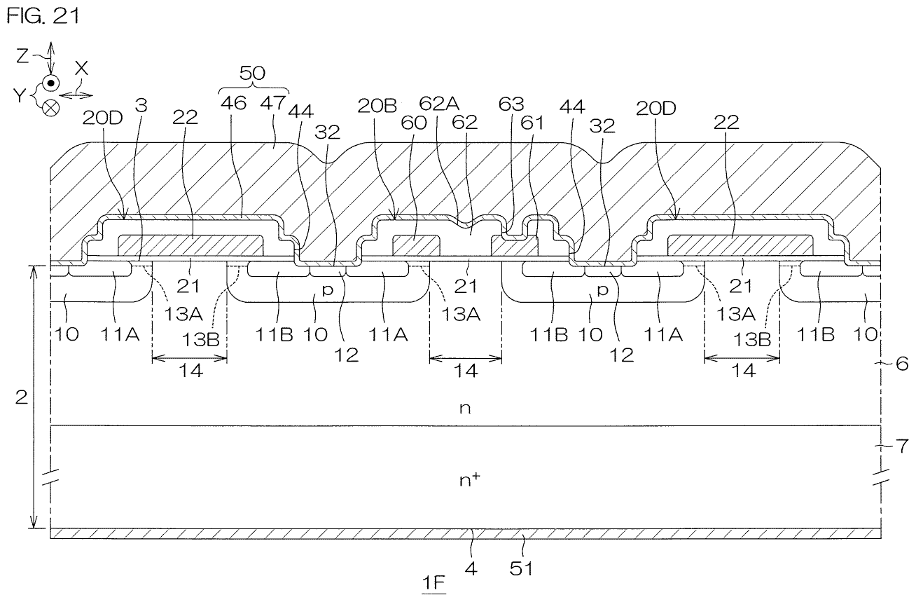

FIG. 20 is an enlarged plan view showing a layout example of an active region 8 of an SiC semiconductor device 1F according to a sixth embodiment. FIG. 21 is a cross-sectional view taken along line XXI-XXI shown in FIG. 20. The SiC semiconductor device 1F simultaneously includes both one or more second planar structures 20B and one or more fourth planar structures 20D.

The gate-source capacitance Cgs of the fourth planar structure 20D is greater than the gate-source capacitance Cgs of the second planar structure 20B. The gate-drain capacitance Cdg of the fourth planar structure 20D is greater than the gate-drain capacitance Cdg of the second planar structure 20B.

FIGS. 20 and 21 illustrate an example in which the SiC semiconductor device 1F includes the second planar structure 20B (see FIG. 13) according to the first configuration example. As a matter of course, the SiC semiconductor device 1F may include at least one of the second planar structures 20B (see FIGS. 14A to 14E) according to the second to sixth configuration examples instead of or in addition to the second planar structure 20B (see FIG. 13) according to the first configuration example.

The number of the second planar structures 20B and the number of the fourth planar structures 20D are appropriately adjusted in accordance with the feedback capacitance Crss to be achieved. For example, the SiC semiconductor device IF may have a layout portion in which a plurality of second planar structures 20B and at least one fourth planar structure 20D are alternately arranged in the first direction X. For example, the SiC semiconductor device IF may have a layout portion in which at least one second planar structure 20B and a plurality of fourth planar structures 20D are alternately arranged in the first direction X.

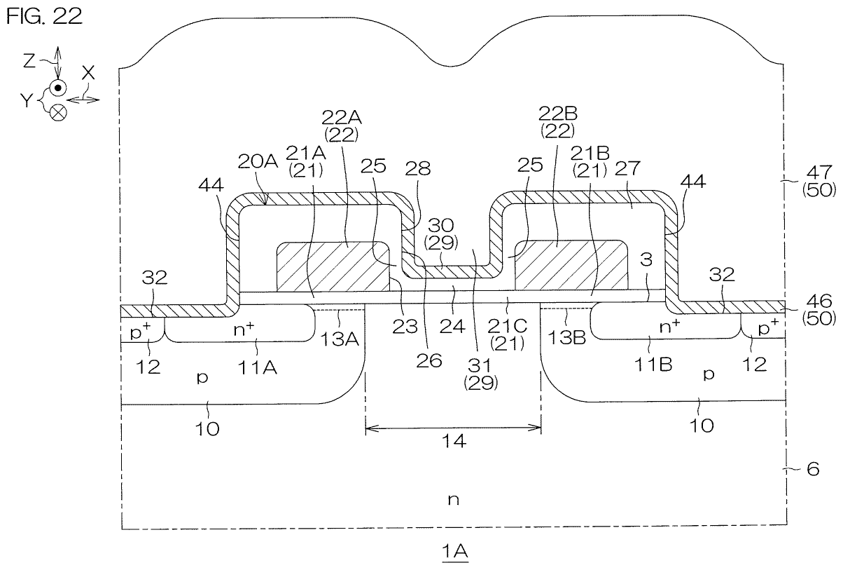

The embodiments described above can be implemented in yet other embodiments. For example, in each embodiment described above, the planar insulating film 27 having a portion extending in the horizontal direction along the first channel covering portion 21A and the second channel covering portion 21B is shown. However, as illustrated in FIG. 22 illustrating a cross-sectional view of a modification example of the planar insulating film 27, the planar insulating film 27 that does not have a portion extending in the horizontal direction in one or both of the first channel covering portion 21A and the second channel covering portion 21B may be formed.

In each of the embodiments described above, a configuration in which the relationship between the a-axis direction and the m-axis direction is interchanged may be adopted. A specific configuration in this case can be obtained by interchanging the “a-axis direction (off direction)” and the “m-axis direction (direction orthogonal to the off direction)” in the above description and the accompanying drawings.

In each of the embodiments described above, a structure in which the conductivity type of the “n-type” semiconductor region is inverted to the “p-type” and the conductivity type of the “p-type” semiconductor region is inverted to the “n-type” may be adopted. A specific configuration in this case can be obtained by replacing the “n-type” with the “p-type” at the same time as replacing the “p-type” with the “n-type” in the above description and accompanying drawings.

In each of the embodiments described above, the chip 2 including the SiC monocrystal is adopted. However, the chip 2 may include a monocrystal of a wide band gap semiconductor other than the SiC monocrystal. The wide bandgap semiconductor is a semiconductor that has a greater bandgap than the bandgap of silicon. Examples of the monocrystal of the wide bandgap semiconductor include gallium nitride, diamond, gallium oxide, etc. As a matter of course, the chip 2 may include a silicon monocrystal.

In each embodiment described above, the n-type drain region 7 is shown. However, the semiconductor region of the p-type may be adopted instead of the n-type drain region 7. In this case, an insulated gate bipolar transistor (IGBT) structure is formed instead of the MISFET structure. In this case, in the above description, the “source” of the MISFET structure is replaced with an “emitter” of the IGBT structure, and the “drain” of the MISFET structure is replaced with a “collector” of the IGBT structure. The p-type semiconductor region may be an impurity region that includes a p-type impurity introduced into the surface layer portion of the second main surface 4 of the chip 2 (the drift region 6) by an ion implantation method.

Hereinafter, examples of features extracted from this description and the attached drawings shall be indicated. Hereinafter, the alphanumeric characters, etc., in parentheses represent the corresponding components, etc., in the embodiments described above, but are not intended to limit the scope of respective clauses to the embodiments described above. A “semiconductor device” in the following clauses may be replaced with an “SiC semiconductor device,” a “wide bandgap semiconductor device,” a “semiconductor switching device,” a “MISFET device,” an “IGBT device, etc., as necessary.

[A1] A semiconductor device (1A to 1F) comprising: a chip (2) having a main surface (3); a channel region (13A, 13B) formed in a surface layer portion of the main surface (3); a drift region (6, 14) adjacent to the channel region (13A, 13B) in the surface layer portion of the main surface (3); a gate insulating film (21) that is formed on the main surface (3) and has a channel covering portion (21A, 21B) which covers the channel region (13A, 13B) and a drift covering portion (21C) which covers the drift region (6, 14); a planar gate electrode (22, 60) that is arranged on the channel covering portion (21A, 21B) and opposes the channel region (13A, 13B) across the channel covering portion (21A, 21B) in a vertical direction (Z); and a planar source electrode (29, 61) that is arranged on the drift covering portion (21C) at an interval from the planar gate electrode (22, 60) such as to oppose the planar gate electrode (22, 60) in a horizontal direction (X, Y) and opposes the drift region (6, 14) across the drift covering portion (21C) in the vertical direction (Z).

[A2] The semiconductor device (1A to 1F) according to A1, wherein the planar source electrode (29, 61) includes a different conductive material from the planar gate electrode (22, 60).

[A3] The semiconductor device (1A to 1F) according to A1, wherein the planar source electrode (29, 61) includes the same type of conductive material as the planar gate electrode (22, 60).

[A4] The semiconductor device (1A to 1F) according to any one of A1 to A3, wherein the planar gate electrode (22, 60) is led out from above the channel covering portion (21A, 21B) onto the drift covering portion (21C) and has a portion opposing the drift region (6, 14) across the drift covering portion (21C) in the vertical direction (Z).

[A5] The semiconductor device (1A to 1F) according to any one of A1 to A4, further comprising: a planar insulating film (27) that covers the planar gate electrode (22, 60); and a source pad (50) arranged on the planar insulating film (27).

[A6] The semiconductor device (1A to 1F) according to A5, wherein the source pad (50) includes at least a part of the planar source electrode (29, 61).

[A7] The semiconductor device (1A to 1F) according to A5, wherein the source pad (50) is constituted of an electrode different from at least a part of the planar source electrode (29, 61) and has a portion physically and electrically connected to at least a part of the planar source electrode (29, 61).

[A8] The semiconductor device (1A to 1F) according to any one of A1 to A7, further comprising: a separation insulating film (25, 62) that is arranged on the drift covering portion (21C) and has a portion opposing the drift region (6, 14) across the drift covering portion (21C) in the vertical direction (Z); and wherein the planar source electrode (29, 61) opposes the planar gate electrode (22, 60) across the separation insulating film (25, 62) in the horizontal direction (X, Y) and is electrically insulated from the planar gate electrode (22, 60) by the separation insulating film (25, 62).

[A9] The semiconductor device (1A to 1F) according to A8, wherein the separation insulating film (25, 62) extends in the vertical direction (Z) along a wall surface of the planar gate electrode (22, 60) and is connected to the gate insulating film (21).

[A10] The semiconductor device (1A to 1F) according to any one of A1 to A9, further comprising: an intermediate insulating film (24) that has a thickness less than a thickness of the planar gate electrode (22, 60) and covers the drift covering portion (21C) at an interval from an electrode surface of the planar gate electrode (22, 60) toward the gate insulating film (21) side; and wherein the planar source electrode (29, 61) is arranged on the intermediate insulating film (24) and opposes the drift region (6, 14) across the intermediate insulating film (24) and the drift covering portion (21C) in the vertical direction (Z).

[A11] The semiconductor device (1A to 1F) according to A10, wherein the intermediate insulating film (24) covers the drift covering portion (21C) in a film shape and has a portion in contact with the wall surface of the planar gate electrode (22, 60).

[A12] The semiconductor device (1A to 1F) according to any one of A1 to A11, wherein the channel regions (13A, 13B) are formed at an interval in the surface layer portion of the main surface (3), the drift region (6, 14) is defined in a region between the channel regions (13A, 13B), the gate insulating film (21) has the channel covering portions (21A, 21B) that cover the channel regions (13A, 13B), the planar gate electrode (22, 60) has a through hole (23) through which the drift covering portion (21C) is exposed and electrode portions (22A, 22B) each defined on the channel covering portions (21A, 21B) by the through hole (23) such as to oppose the channel regions (13A, 13B) across the channel covering portions (21A, 21B), and the planar source electrode (29, 61) is arranged in the through hole (23) and opposes the electrode portions (22A, 22B) in the horizontal direction (X, Y).

[A13] The semiconductor device (1A to 1F) according to A12, wherein the planar gate electrode (22, 60) is defined in an annular shape, a stripe shape, or a lattice shape by one or more through holes (23) in a plan view.

[A14] The semiconductor device (1A to 1F) according to any one of A1 to A13, wherein the chip (2) is constituted of an SiC chip (2) including an SiC monocrystal.

[A15] A semiconductor device (1A to 1F) including: a chip (2) having a main surface (3); a first channel region (13A) formed in a surface layer portion of the main surface (3); a second channel region (13B) formed in the surface layer portion of the main surface (3) at an interval from the first channel region (13A); a drift region (6, 14) defined in a region between the first channel region (13A) and the second channel region (13B) in the surface layer portion of the main surface (3); a gate insulating film (21) that is formed on the main surface (3) and has a first portion (21A) which covers the first channel region (13A) and a second portion (21B) which covers the second channel region (13B); a planar gate electrode (22, 60) that is arranged on the first portion (21A) and opposes the first channel region (13A) across the first portion (21A) in a vertical direction (Z); and a planar source electrode (29, 61) that is arranged on the second portion (21B) such as to oppose the planar gate electrode (22, 60) in a horizontal direction (X, Y) and opposes the second channel region (13B) across the second portion (21B) in the vertical direction (Z).

[A16] The semiconductor device (1A to 1F) according to A15, wherein the gate insulating film (21) has a third portion (21C) which covers the drift region (6, 14), the planar gate electrode (22, 60) is led out from the first portion (21A) to the third portion (21C) and has a portion opposing the drift region (6, 14) across the third portion (21C) in the vertical direction (Z), and the planar source electrode (29, 61) is led out from the second portion (21B) to the third portion (21C) and has a portion opposing the drift region (6, 14) across the third portion (21C) in the vertical direction (Z).

[A17] The semiconductor device (1A to 1F) according to A15 or A16, wherein the planar source electrode (29, 61) includes the same conductive material as the planar gate electrode (22, 60).

[A18] The semiconductor device (1A to 1F) according to A17, wherein the planar gate electrode (22, 60) includes polysilicon, and the planar source electrode (29, 61) includes polysilicon.

[A19] The semiconductor device (1A to 1F) according to any one of A15 to A18, further comprising: a separation insulating film (25, 62) that is interposed between the planar gate electrode (22, 60) and the planar source electrode (29, 61) and opposes the drift region (6, 14) in the vertical direction (Z).

[A20] The semiconductor device (1A to 1F) according to A19, wherein a thickness of the separation insulating film (25, 62) in the horizontal direction (X, Y) is greater than a thickness of the gate insulating film (21) in the vertical direction (Z).

[A21] The semiconductor device (1A to 1F) according to any one of A15 to A20, further comprising: a planar insulating film (27) that covers the planar gate electrode (22, 60) and the planar source electrode (29, 61); and a source pad (50) that is arranged on the planar insulating 5 film (27), electrically insulated from the planar gate electrode (22, 60) by the planar insulating film (27), and electrically connected to the planar source electrode (29, 61) through the planar insulating film (27).

[A22] The semiconductor device (1A to 1F) according to any one of A15 to A21, wherein the chip (2) is constituted of an SiC chip (2) including an SiC monocrystal.

While the specific embodiments have been described in detail above, these are merely specific examples used to clarify the technical contents. The various technical ideas extracted from this Description can be combined as appropriate with each other without being limited by the order of description, the order of configuration examples, etc., in the description.

What is claimed is:

1. An SiC semiconductor device comprising:
an SiC chip having a main surface;
a channel region formed in a surface layer portion of the main surface;
a drift region adjacent to the channel region in the surface layer portion of the main surface;
a gate insulating film that is formed on the main surface and has a channel covering portion which covers the channel region and a drift covering portion which covers the drift region;
a planar gate electrode that is arranged on the channel covering portion and opposes the channel region across the channel covering portion in a vertical direction; and
a planar source electrode that is arranged on the drift covering portion at an interval from the planar gate electrode such as to oppose the planar gate electrode in a horizontal direction and opposes the drift region across the drift covering portion in the vertical direction.

2. The SiC semiconductor device according to claim 1,
wherein the planar source electrode includes a different conductive material from the planar gate electrode.

3. The SiC semiconductor device according to claim 1,
wherein the planar source electrode includes the same type of conductive material as the planar gate electrode.

4. The SiC semiconductor device according to claim 1,
wherein the planar gate electrode is led out from above the channel covering portion onto the drift covering portion and has a portion opposing the drift region across the drift covering portion in the vertical direction.

5. The SiC semiconductor device according to claim 1, further comprising:
a planar insulating film that covers the planar gate electrode; and
a source pad arranged on the planar insulating film.

6. The SiC semiconductor device according to claim 5,
wherein the source pad includes at least a part of the planar source electrode.

7. The SiC semiconductor device according to claim 5,
wherein the source pad is constituted of an electrode different from at least a part of the planar source electrode and has a portion physically and electrically connected to at least a part of the planar source electrode.

8. The SiC semiconductor device according to claim 1, further comprising:
a separation insulating film that is arranged on the drift covering portion and has a portion opposing the drift region across the drift covering portion in the vertical direction; and
wherein the planar source electrode opposes the planar gate electrode across the separation insulating film in the horizontal direction and is electrically insulated from the planar gate electrode by the separation insulating film.

9. The SiC semiconductor device according to claim 8,
wherein the separation insulating film extends in the vertical direction along a wall surface of the planar gate electrode and is connected to the gate insulating film.

10. The SiC semiconductor device according to claim 1, further comprising:
an intermediate insulating film that has a thickness less than a thickness of the planar gate electrode and covers the drift covering portion at an interval from an electrode surface of the planar gate electrode toward the gate insulating film side; and
wherein the planar source electrode is arranged on the intermediate insulating film and opposes the drift region across the intermediate insulating film and the drift covering portion in the vertical direction.

11. The SiC semiconductor device according to claim 10,
wherein the intermediate insulating film covers the drift covering portion in a film shape and has a portion in contact with the wall surface of the planar gate electrode.

12. The SiC semiconductor device according to claim 1,
wherein the channel regions are formed at an interval in the surface layer portion of the main surface,
the drift region is defined in a region between the channel regions,
the gate insulating film has the channel covering portions that cover the channel regions,
the planar gate electrode has a through hole through which the drift covering portion is exposed and electrode portions each defined on the channel covering portions by the through hole such as to oppose the channel regions across the channel covering portions, and
the planar source electrode is arranged in the through hole and opposes the electrode portions in the horizontal direction.

13. The SiC semiconductor device according to claim 12,
wherein the planar gate electrode is defined in an annular shape, a stripe shape, or a lattice shape by one or more through holes in a plan view.

14. An SiC semiconductor device comprising:
an SiC chip having a main surface;
a first channel region formed in a surface layer portion of the main surface;
a second channel region formed in the surface layer portion of the main surface at an interval from the first channel region;
a drift region defined in a region between the first channel region and the second channel region in the surface layer portion of the main surface;
a gate insulating film that is formed on the main surface and has a first portion which covers the first channel region and a second portion which covers the second channel region;
a planar gate electrode that is arranged on the first portion and opposes the first channel region across the first portion in a vertical direction; and
a planar source electrode that is arranged on the second portion such as to oppose the planar gate electrode in a horizontal direction and opposes the second channel region across the second portion in the vertical direction.

15. The SiC semiconductor device according to claim 14,
wherein the gate insulating film has a third portion which covers the drift region,
the planar gate electrode is led out from the first portion to the third portion and has a portion opposing the drift region across the third portion in the vertical direction, and
the planar source electrode is led out from the second portion to the third portion and has a portion opposing the drift region across the third portion in the vertical direction.

16. The SiC semiconductor device according to claim 14,
wherein the planar source electrode includes the same conductive material as the planar gate electrode.

17. The SiC semiconductor device according to claim 16,
wherein the planar gate electrode includes polysilicon, and
the planar source electrode includes polysilicon.

18. The SiC semiconductor device according to claim 14, further comprising:
a separation insulating film that is interposed between the planar gate electrode and the planar source electrode and opposes the drift region in the vertical direction.

19. The SiC semiconductor device according to claim 18,
wherein a thickness of the separation insulating film in the horizontal direction is greater than a thickness of the gate insulating film in the vertical direction.

20. The SiC semiconductor device according to claim 14, further comprising:
a planar insulating film that covers the planar gate electrode and the planar source electrode; and
a source pad that is arranged on the planar insulating film, electrically insulated from the planar gate electrode by the planar insulating film, and electrically connected to the planar source electrode through the planar insulating film.
